(19) United States
(12) Patent Application Publication
(10) Pub. No.: US 2025/0311252 A1
(43) Pub. Date: Oct. 2, 2025

(54) INTEGRATED CIRCUIT STRUCTURES WITH CAPACITORS WITH POROUS MATERIALS

(71) Applicant: Intel Corporation, Santa Clara, CA (US)

(72) Inventors: Abhishek A. Sharma, Portland, OR (US); Sagar Suthram, Portland, OR (US); Wilfred Gomes, Portland, OR (US); Tahir Ghani, Portland, OR (US); Anand S. Murthy, Portland, OR (US)

(73) Assignee: Intel Corporation, Santa Clara, CA (US)

(21) Appl. No.: 18/617,908

(22) Filed: Mar. 27, 2024

(51) Int. Cl. H01L 29/94; H01L 23/522; H01L 29/66

(52) U.S. Cl. CPC H10D 1/66; H01L 23/5223; H10D 1/042; H10D 1/047; H10D 1/712; H10D 1/716

(57) ABSTRACT

Disclosed herein are IC structures with capacitors with porous materials. In one aspect, an IC structure may include a capacitor having first and second electrodes, and an insulator therebetween, wherein the first electrode includes a porous semiconductor material with dopants. In another aspect, an IC structure may include a capacitor having first and second electrodes, and an insulator therebetween, wherein the insulator includes a porous semiconductor material with oxygen.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize fabrication and performance of each component becomes increasingly significant.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIGS. 1A-1J provide schematic illustrations of integrated circuit (IC) structures in which capacitor banks may be implemented, according to some embodiments of the present disclosure.

FIGS. 2A-2J illustrate example cross-sectional side views of IC structures with capacitor banks, according to some embodiments of the present disclosure.

FIGS. 3A-3D illustrate example cross-sectional side views of capacitors that may be used in capacitor banks, according to some embodiments of the present disclosure.

FIGS. 4A-4B provide schematic illustrations of example top-down views of capacitor banks, according to some embodiments of the present disclosure.

FIGS. 5A-5B illustrate example cross-sectional side views of capacitors of a capacitor bank coupled to first and second conductive lines, according to some embodiments of the present disclosure.

FIG. 6 provides a schematic illustration of an example top-down view of an IC structure with multiple capacitor banks, according to some embodiments of the present disclosure.

FIGS. 7A-7B illustrate examples of a cross-sectional side view and a top-down view of an IC structure after a first stage of fabrication of a capacitor with a porous material being used as a capacitor insulator, according to some embodiments of the present disclosure.

FIGS. 8A-8B illustrate examples of a cross-sectional side view and a top-down view of an IC structure after a second stage of fabrication of a capacitor with a porous material being used as a capacitor insulator, according to some embodiments of the present disclosure.

FIGS. 9A-9B illustrate examples of a cross-sectional side view and a top-down view of an IC structure after a first stage of fabrication of a capacitor with a porous material being used as a capacitor electrode, according to some embodiments of the present disclosure.

FIGS. 10A-10B illustrate examples of a cross-sectional side view and a top-down view of an IC structure after a second stage of fabrication of a capacitor with a porous material being used as a capacitor electrode, according to some embodiments of the present disclosure.

FIGS. 11A-11B illustrate examples of a cross-sectional side view and a top-down view of an IC structure with a trench capacitor with a porous material being used as a capacitor electrode, according to some embodiments of the present disclosure.

FIGS. 12A-12B illustrate examples of a cross-sectional side view and a top-down view of an IC structure with a via capacitor with a porous material being used as a capacitor electrode, according to some embodiments of the present disclosure.

FIGS. 13A-13B illustrate examples of a cross-sectional side view and a top-down view of an IC structure with a pillar capacitor with a porous material being used as a capacitor electrode, according to some embodiments of the present disclosure.

FIG. 14 illustrates top views of a wafer and dies that may include one or more IC structures with one or more capacitors with porous materials, according to some embodiments of the present disclosure.

FIG. 15 illustrates a cross-sectional side view of an IC device assembly that may include one or more IC structures with one or more capacitors with porous materials in accordance with any of the embodiments disclosed herein.

FIG. 16 illustrates a block diagram of an example computing device that may include one or more IC structures with one or more capacitors with porous materials in accordance with any of the embodiments disclosed herein.

### DETAILED DESCRIPTION

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

For purposes of illustrating IC structures with capacitors with porous materials, described herein, it might be useful to first understand phenomena that may come into play in certain IC arrangements. The following foundational information may be viewed as a basis from which the present disclosure may be properly explained. Such information is offered for purposes of explanation only and, accordingly, should not be construed in any way to limit the broad scope of the present disclosure and its potential applications.

Capacitors are used in many different electronic device designs, where their ability to store and release electrical energy makes them versatile and useful components. For example, capacitors play a crucial role in power delivery within electronic circuits where they can serve as components designed to store and release electrical energy, as needed, in the form of an electric field. In another example, capacitors may be used to smooth out voltage fluctuations and provide a stable DC voltage. In such implementations, capacitors can act as temporary energy storage devices, releasing stored energy when the voltage decreases and absorbing excess energy when the voltage increases, which may help maintaining a more constant voltage level in the circuit. In yet another example, capacitors may be employed in power supply circuits for filtering and decoupling purposes. In such implementations, capacitors can filter out high-frequency noise or ripple in the power supply, ensuring a cleaner and more stable DC voltage. Additionally, capacitors can decouple different sections of a circuit, preventing unwanted interactions and ensuring that one part of the circuit doesn't affect another. Furthermore, capacitors can contribute to voltage regulation by providing additional energy during transient load changes. They can help stabilize the voltage and prevent voltage drops when the demand for power increases suddenly.

Capacitors with porous materials, and associated IC structures, devices and systems, are disclosed. The capacitance of a capacitor depends on several factors, including its physical characteristics and the properties of the capacitor insulator material between its electrodes. The capacitance (C) of a capacitor is mathematically expressed by the formula:

$$C = \frac{ε \cdot A}{d} ,$$

where C is the capacitance, ε is the permittivity of the capacitor insulator, A is the area of one of the capacitor electrodes, and d is the distance separating capacitor electrodes. Embodiments of the present disclosure are based on recognition that capacitance of a capacitor may be increased significantly if either a capacitor insulator or a capacitor electrode of a capacitor is a porous material, which could significantly increase the area A of the capacitor electrode(s). Embodiments of the present disclosure are further based on recognition that semiconductor materials may be particularly advantageous for being included as porous materials in such capacitors because semiconductor materials may either be made electrically conductive (e.g., by adding dopants) or be made electrically insulative (e.g., by oxidation). A porous semiconductor material made electrically conductive may be used as one of the capacitor electrodes, while a porous semiconductor material made electrically insulative may be used as the capacitor insulator. Other technical effects will be evident from various embodiments described here.

In one aspect, an IC structure may include a capacitor having first and second electrodes, and an insulator therebetween, wherein the first electrode includes a porous semiconductor material with dopants. For example, an IC structure may include a structure of a semiconductor material, the structure having a first side and a second side opposite the first side, wherein the semiconductor material is a porous semiconductor material having pores extending into the structure from the first side towards the second side, and wherein the semiconductor material includes dopants. Such an IC structure may further include an insulator on sidewalls of the pores and a conductive material at least partially filling the pores with the insulator material on the sidewalls of the pores. In another aspect, an IC structure may include a capacitor having first and second electrodes, and an insulator therebetween, wherein the insulator includes a porous semiconductor material with oxygen. For example, an IC structure may include a structure of an insulator material, the structure having a first side and a second side opposite the first side, wherein the insulator material is a porous insulator material having first pores extending into the structure from the first side towards the second side and further having second pores extending into the structure from the second side towards the first side, and wherein the insulator material includes a semiconductor material and oxygen. In such an IC structure, a first conductive material at least partially filling the first pores may serve as a first electrode of a capacitor, and a second conductive material at least partially filling the second pores may serve as a second electrode of a capacitor, with the insulator material being a capacitor insulator separating the first conductive material and the second conductive material.

In some embodiments, one or more capacitors with porous materials as described herein may be part of a capacitor bank that may be used to support power delivery to active components of an IC structure, e.g., to transistors or other components of a front-end-of-line (FEOL) layer or of a back-end-of-line (BEOL) of an IC structure.

FEOL and BEOL are two distinct stages in semiconductor manufacturing (e.g., in advanced complementary metal-oxide-semiconductor (CMOS) processes), each playing an important role in the fabrication of IC structures (or, more generally, of semiconductor devices). These terms refer to the chronological order of processes involved in creating an IC structure. The FEOL processes occur at the front or early stages of semiconductor manufacturing, typically on the surface of a semiconductor (e.g., silicon) wafer. FEOL involves the fabrication of the active components of the semiconductor device, such as transistors and other active devices. The BEOL processes occur after the completion of the FEOL processes and may involve the entire wafer, including the areas where active components have been created during the FEOL stage. The BEOL involves providing the interconnection of the active devices of the FEOL and the creation of the final wiring and metal layers that connect the transistors and other components. The BEOL is typically focused on creating the metal interconnects that form the circuit paths.

Power delivery to active components of IC structures is not an easy task, especially as more and more components are built in multiple layers over a wafer. Disclosed herein are IC structures with capacitor banks for power delivery, where at least one of the capacitor banks may include one or more capacitors with porous materials as described herein. A capacitor bank may include a plurality of capacitors located adjacent to each other. Each capacitor may include a first capacitor electrode, a second capacitor electrode, and a capacitor insulator separating the first and second capacitor electrodes. Multiple capacitors may be described as belonging to a bank of capacitors if they are located relatively close to one another (e.g., when adjacent capacitors of a capacitor bank are closer to one another than to most of the other components of an IC structure) and if their first electrodes are all coupled to a single first conductive line, while their second electrodes are all coupled to a single second conductive line. Multiple capacitors of such a capacitor bank may collectively act as a single large capacitor that may be capable of storing a much larger charge than individual capacitors of the bank. Such capacitor banks may be used to assist power delivery to various components of IC structures, e.g., to transistors or other components of the FEOL layers. For example, in various implementations, capacitor banks as described herein may be used for storing and releasing electrical energy, regulating voltage, filtering noise, improving transient response, and/or providing other functions for stable and reliable operation of electronic circuits.

Conventionally, power delivery has been done from the front side, by routing power interconnects from the top of the IC structures down to the active devices of the FEOL. However, as more and more components are built in multiple layers on the front sides of wafers, front side power delivery to these components becomes challenging. Capacitor banks as described herein may be particularly beneficial when provided on the back side of wafers or dies. An example IC structure may include a device layer (e.g., an FEOL layer) comprising a plurality of transistors, the device layer having a first side and a second side opposite the first side; one or more backend layers (e.g., BEOL layers) at the first side of the device layer, the one or more backend layers comprising backend interconnects coupled to one or more of the plurality of transistors; and one or more backside layers at the second side of the device layer (thus, the device layer may be between the one or more backend layers and the one or more backside layers), wherein the one or more backside layers may include a bank of capacitors, a first conductive line, and a second conductive line, such that first electrodes of the capacitors are coupled to the first conductive line, and second electrodes of the capacitors are coupled to the second conductive line. Providing capacitor banks for power delivery on the back side of the IC structures may increase integration density on the front side of the IC structures (e.g., the freed-up space on the front side can be utilized for additional active components, enabling higher levels of integration), reduce interference and improve signal integrity on the front side, contribute to better electromagnetic compatibility (EMC) by reducing the potential for interference between power delivery and signal lines, improve thermal management (e.g., potentially reducing the impact of localized heating on the device's performance), and help realize full benefits of three-dimensional (3D) IC integration where multiple layers of active devices are stacked on top of each other.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−20%, e.g., within +/−5% or within +/−2% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

Although certain elements may be referred to in the singular herein, such elements may include multiple sub-elements. For example, “an insulator material” may include one or more insulator materials. The term “insulating” and variations thereof (e.g., “insulative” or “insulator”) means “electrically insulating,” the term “conducting” and variations thereof (e.g., “conductive” or “conductor”) means “electrically conducting,” unless otherwise specified. For example, the term “insulator material” may refer to solid materials (and/or liquid materials that solidify after processing as described herein) that are substantially electrically non-conducting. They may include, as examples and not as limitations, organic polymers and plastics, and inorganic materials such as ionic crystals, porcelain, glass, silicon and alumina or a combination thereof. They may include dielectric materials, high polarizability materials, and/or piezoelectric materials. They may be transparent or opaque without departing from the scope of the present disclosure. With reference to optical signals and/or devices, components and elements that operate on or using optical signals, the term “conducting/conductive” can also mean “optically conducting/conductive.”

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

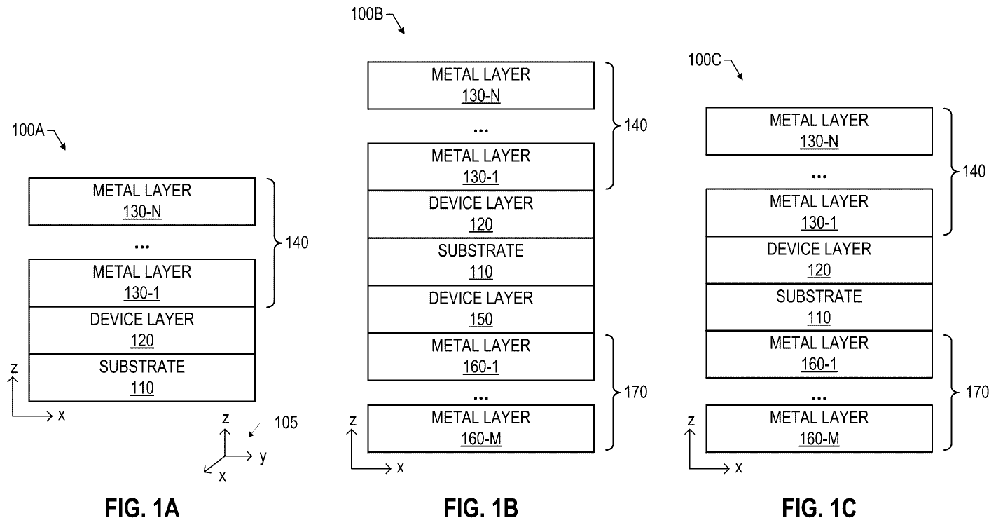

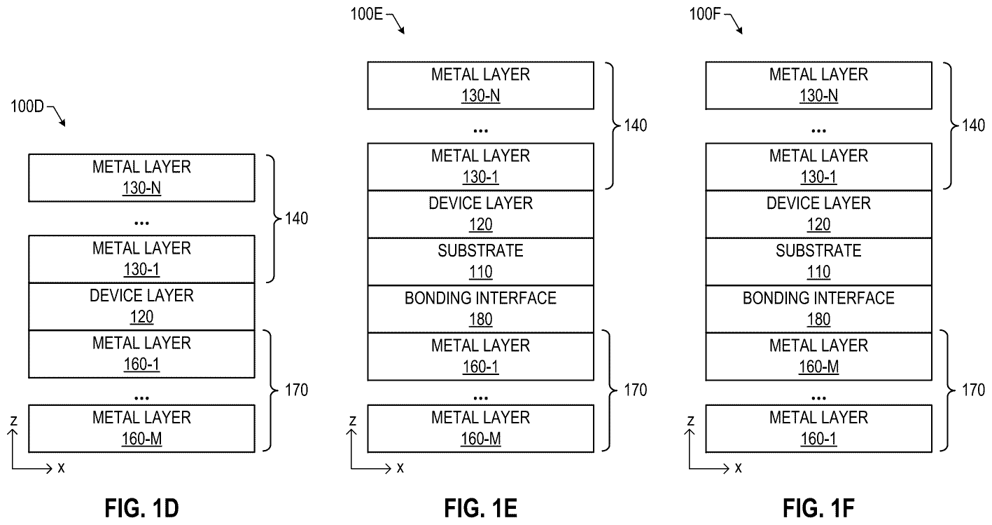

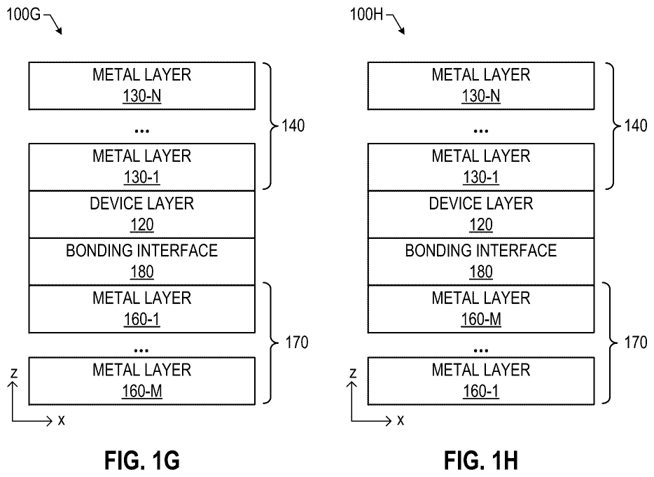

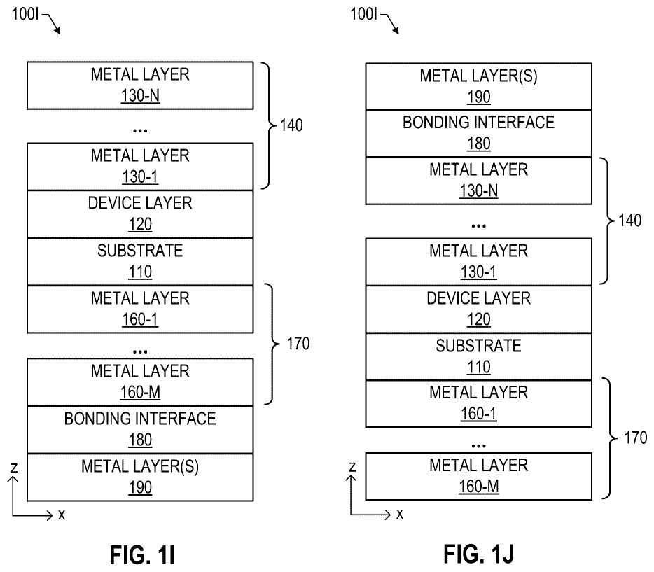

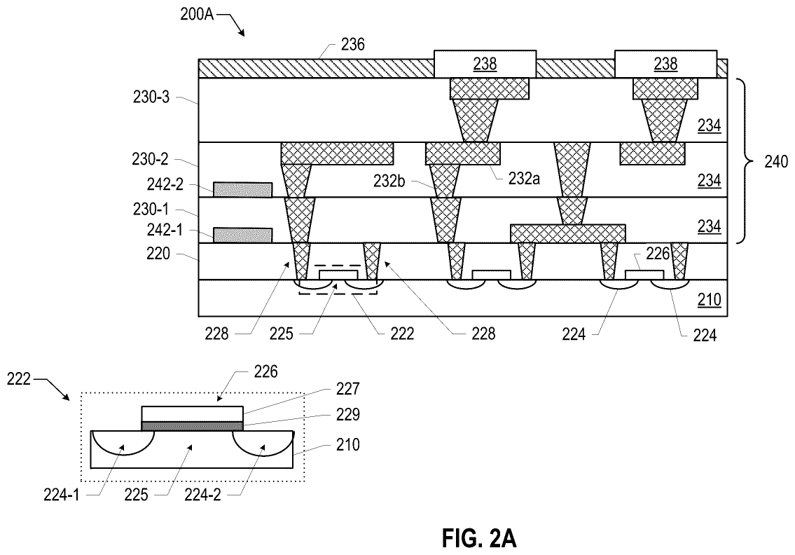

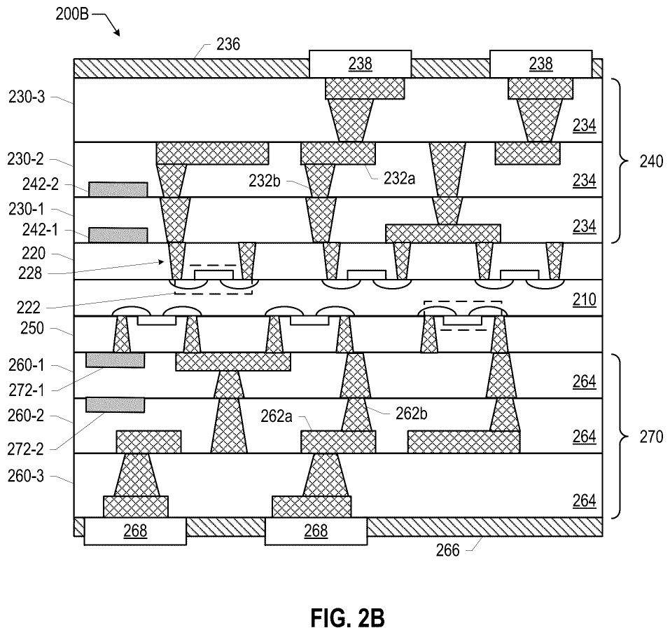

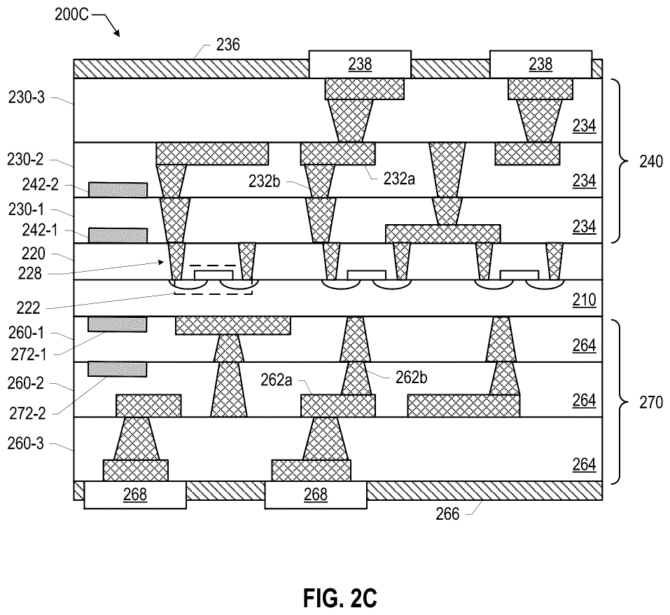

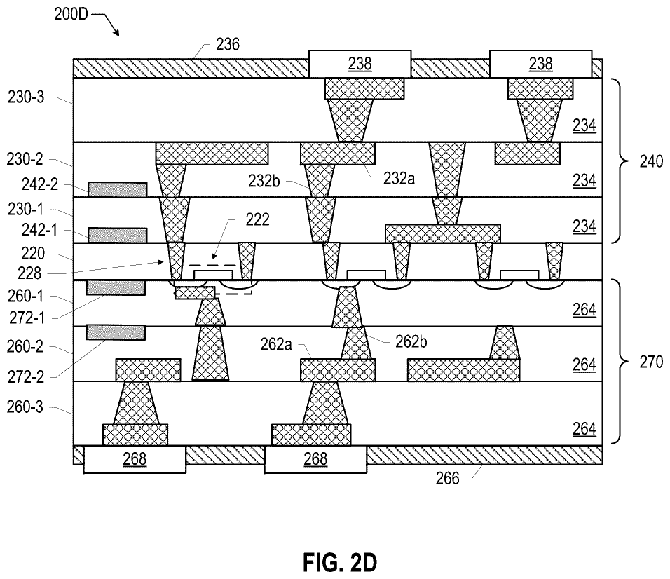

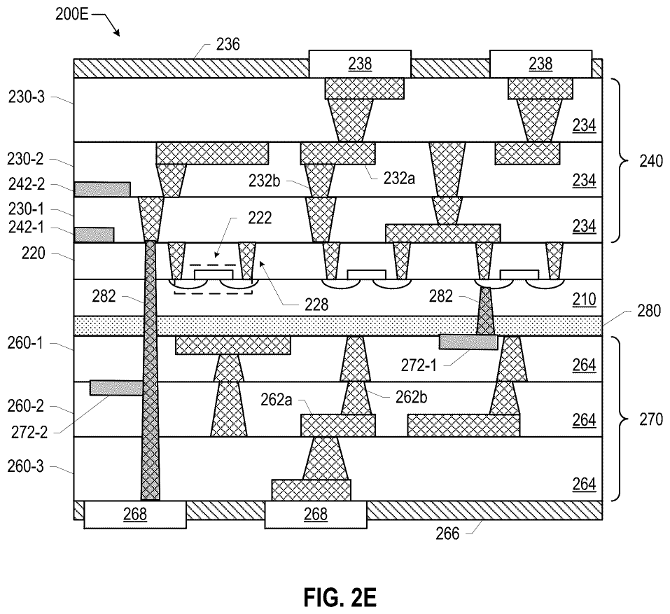

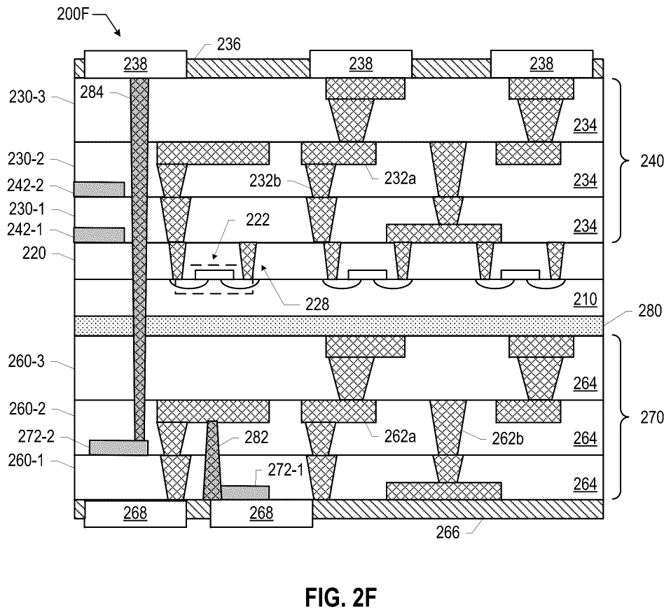

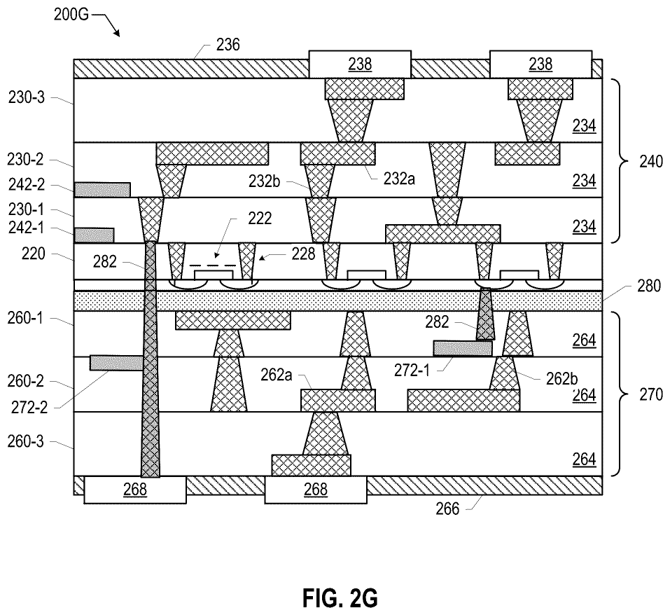

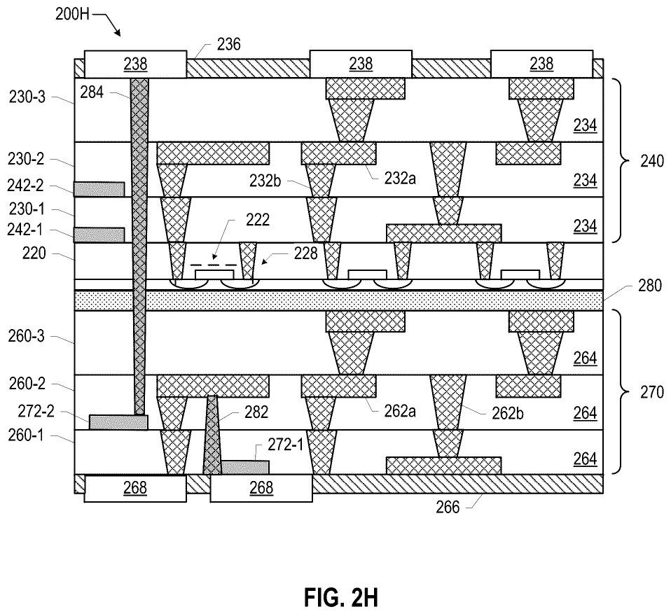

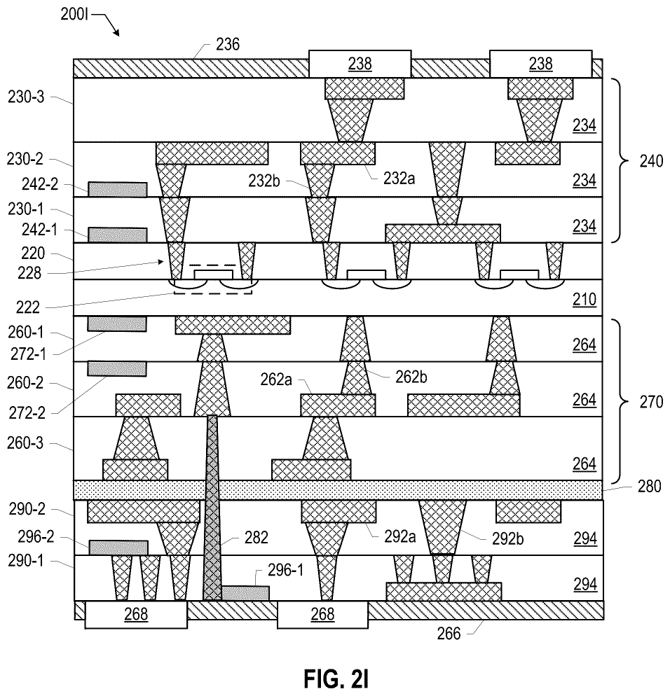

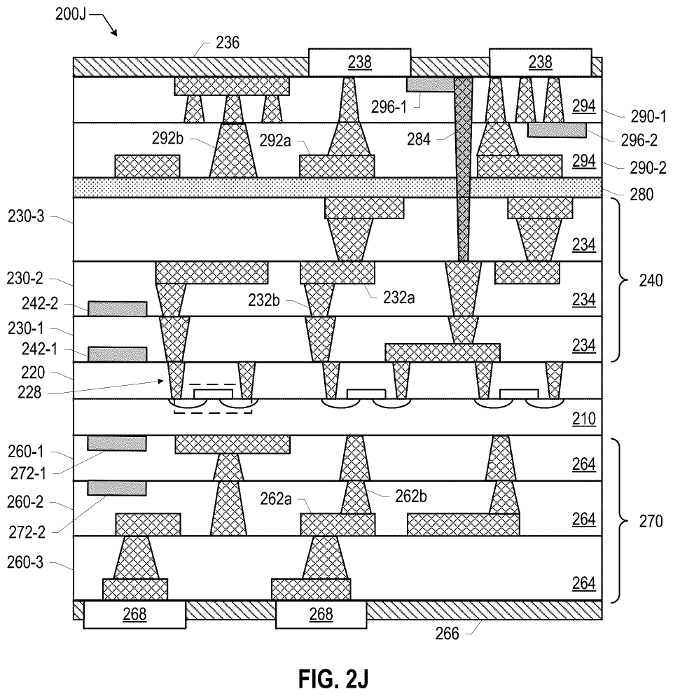

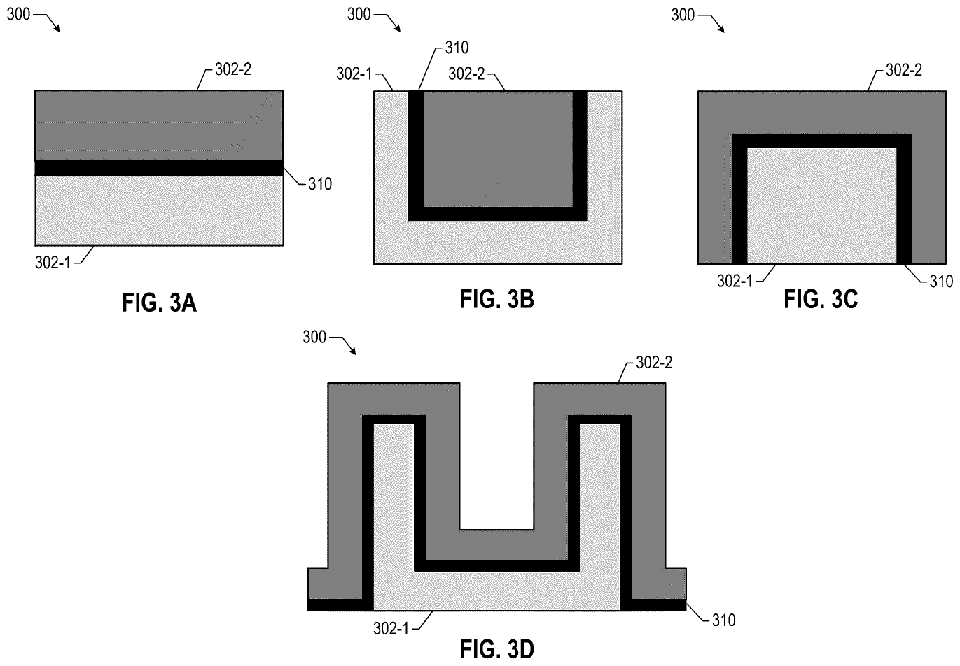

Any of the features discussed with reference to any of accompanying drawings herein may be combined with any other features to form IC structures with capacitors with porous materials, as appropriate. A number of elements of the drawings are shared with others of the drawings; for ease of discussion, a description of these elements is not repeated, and these elements may take the form of any of the embodiments disclosed herein. If multiple instances of certain elements are illustrated, then, in some cases, to not clutter the drawings only some of these elements may be labeled with a reference sign and other ones of these elements are not labeled (e.g., although FIG. 2A illustrates three transistors 222, only one of them is labeled with a reference sign). However, in other cases, for ease of explanation, different instances of a given element in a single drawing may be referred to with numbers 1, 2, and so on, after a dash (e.g., FIG. 2A illustrates two capacitor banks, labeled individually as a first capacitor bank 242-1 and a second capacitor bank 242-2). For convenience, the phrase “FIG. 1” may be used to refer to the collection of drawings of FIGS. 1A-1J, the phrase “FIG. 2” may be used to refer to the collection of drawings of FIGS. 2A-2J, the phrase “FIG. 3” may be used to refer to the collection of drawings of FIGS. 3A-3D, and so on. Similarly, the phrase “IC structures 200” may be used to refer to a collection of IC structures 200A-200J of FIGS. 2A-2J, and so on.

The drawings are not necessarily to scale. In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of capacitors with porous materials as described herein.

Various IC structures with capacitors with porous materials as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

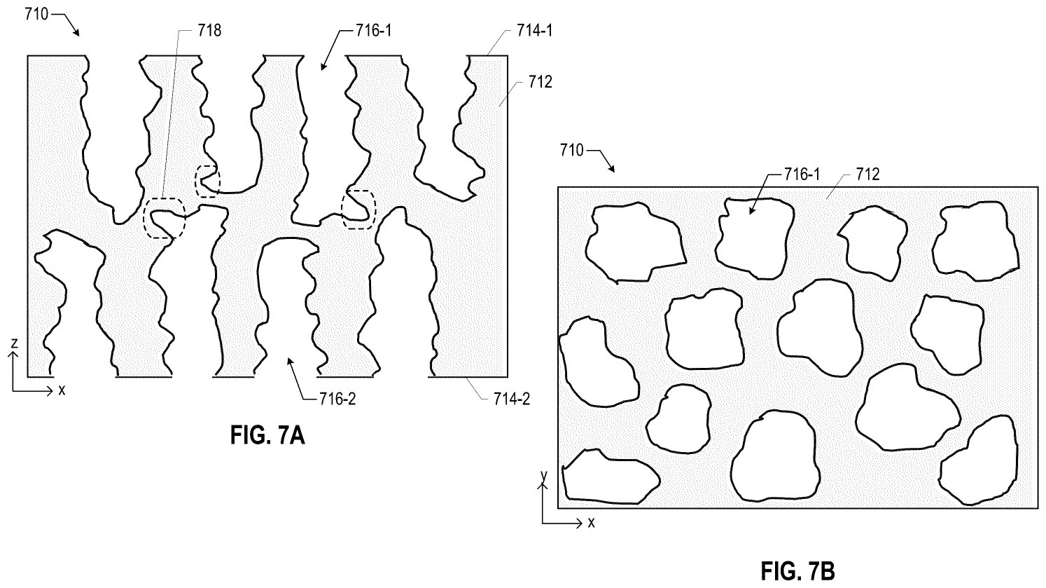

FIGS. 1A-1J provide schematic illustrations of IC structures in which one or more capacitors with porous materials may be implemented, according to some embodiments of the present disclosure, and FIGS. 2A-2J illustrate example cross-sectional side views of the IC structures of FIGS. 1A-1J, according to some embodiments of the present disclosure. In the following, FIGS. 1A-1J and FIGS. 2A-2J refer to capacitor banks (e.g., capacitor banks 242, 272, and 296); however these descriptions are equally applicable to IC structures where any of these capacitor banks is a capacitor bank comprising only one capacitor, which may be a capacitor with a porous material as described herein (e.g., as described with reference to FIGS. 7-13). Thus, in general, any of the capacitor banks described with reference to FIGS. 1A-1J and FIGS. 2A-2J may include a single capacitor with a porous material as described herein and zero or more additional capacitors, which may include capacitors with porous materials as described herein or may include conventional capacitors that do not include porous materials.

FIG. 1A illustrates a cross-sectional view of an example IC structure 100A in which one or more capacitor banks may be implemented, according to some embodiments of the present disclosure, and one example implementation of the IC structure 100A is an IC structure 200A shown in FIG. 2A, according to some embodiments of the present disclosure. FIG. 1A illustrates an example coordinate system 105 with axes x-y-z so that the various planes illustrated in FIGS. 1A and 1n some subsequent drawings may be described with reference to this coordinate system.

As shown in FIG. 1A, in general, the IC structure 100A may include a substrate 110, a device layer 120, and a plurality of metal layers 130, individually labeled as a metal layer 130-1 through metal layer 130-N, where N is an integer greater than 1. Together, the metal layers 130 may be referred to as a metallization stack 140. The illustration of FIG. 1A is intended to provide a general orientation and arrangement of various layers with respect to one another, and, unless specified otherwise in the present disclosure, includes embodiments of the IC structure 100A where portions of elements described with respect to one of the layers shown in FIG. 1A may extend into one or more, or be present in, other layers. Same applies to the subsequent drawings.

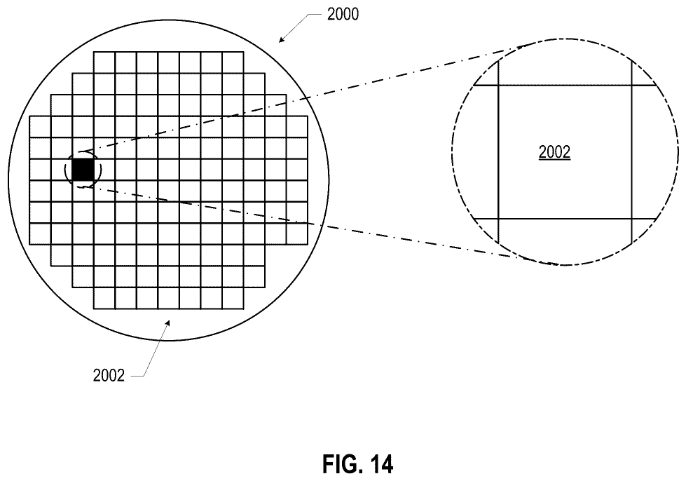

The substrate 110 may be any suitable support over which the device layer 120 and the metallization stack 140 may be provided. For example, the substrate 110 may be a die, a wafer, a chip, or any other suitable support structure. The substrate 110 may, e.g., be the wafer 2000 of FIG. 14, discussed below, and may be, or be included in, a die, e.g., the singulated die 2002 of FIG. 14, discussed below. The substrate 110 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the substrate 110 may be a printed circuit board (PCB) substrate. Although a few examples of materials from which the substrate may be formed are described here, any material that may serve as a foundation upon which a semiconductor device implementing any of the capacitor banks as described herein may be built falls within the spirit and scope of the present disclosure.

The device layer 120 may include any combination of components (e.g., ICs) provided over the substrate 110. For example, in some embodiments, the device layer 120 may include various logic layers, circuits, and devices (e.g., logic transistors) to drive and control a logic IC. In some embodiments, the device layer 120 may include memory devices/circuits. The device layer 120 may also be referred to as a “FEOL layer” and the components of the device layer 120 (e.g., transistors) may be referred to as “frontend components.”

Various layers of the metallization stack 140 may be, or include, BEOL layers, which may also be referred to as “backend layers.” As used herein, the term “metal layer” may refer to a layer above a substrate 110 that includes electrically conductive interconnect structures (e.g., conductive lines and conductive vias) for providing electrical connectivity between different IC components, e.g., between different components of the device layer 120. Metal layers described herein may also be referred to as “metal layers” to indicate that these layers include electrically conductive interconnect structures which may, but does not have to, be metal. Various metal layers of the metallization stack 140 may be used to interconnect the various inputs and outputs of the active components (e.g., transistors) in the device layer 120. Generally speaking, each of the metal layers of the metallization stack 140 may include a conductive line (also sometimes referred to as a “trench,” a “trace,” or a “metal line”) and/or a conductive via. Conductive lines of a metal layer are interconnects configured for transferring signals and power along electrically conductive (e.g., metal) structures extending in the x-y plane (e.g., in the x or y directions), while the conductive vias of a metal layer are configured for transferring signals and power through electrically conductive structures extending in the z-direction, e.g., to any of the adjacent metal layers above or below. Accordingly, conductive vias connect interconnect structures (e.g., conductive lines and/or conductive vias) of one metal layer to interconnect structures of an adjacent metal layer. While referred to as “metal” layers, various layers of the metallization stack 140 may include only certain patterns of conductive metals, e.g., copper (Cu), aluminum (Al), tungsten (W), or cobalt (Co), or metal alloys, or more generally, patterns of an electrically conductive material, formed in a medium of an insulator material such as an interlayer dielectric (ILD). The insulator medium may include any suitable ILD materials such as silicon oxide, carbon-doped silicon oxide, silicon carbide, silicon nitride, aluminum oxide, and/or silicon oxynitride.

FIG. 2A illustrates a cross-sectional side view of an example IC structure 200A that may include one or more capacitor banks in accordance with any of the embodiments disclosed herein.

The IC structure 200A shown in FIG. 2A is an example of the IC structure 100A of FIG. 1A, as explained below.

The IC structure 200A may be formed on a substrate 210, where the substrate 210 may be any suitable support structure as described herein, e.g., the substrate 110 of FIG. 1A and/or the wafer 2000 of FIG. 14. The substrate 210 may be part of a singulated die (e.g., the dies 2002 of FIG. 14) or a wafer (e.g., the wafer 2000 of FIG. 14).

The IC structure 200A may include one or more device layers 220 disposed on the substrate 210, where, together, the one or more device layers 220 may be an example of the device layer 120 of the IC structure 100A. The device layer 220 may include features of one or more transistors 222 (e.g., metal-oxide-semiconductor field-effect transistors (MOSFETs)) formed on the substrate 210, e.g., channel regions/portions of the transistors 222 may be portions of the uppermost layers of the substrate 210. The device layer 220 may include, for example, source and/or drain (S/D) regions 224, gates 226 to control current flow in the transistors 222 between their S/D regions 224, channel regions 225 between S/D regions 224 in each of the transistors 222, and S/D contacts 228 to route electrical signals to/from the S/D regions 224. The transistors 222 may include additional features not depicted for the sake of clarity, such as device isolation regions, gate contacts, and the like. Details of an individual transistor 222, e.g., a transistor 222 enclosed within a dashed contour in the IC structure 200A are shown in FIG. 2A within a dotted contour below the IC structure 200A, where an enlarged version of the transistor 222 is shown. However, the transistors 222 are not limited to the type and configuration depicted in FIG. 2A and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

As shown in FIG. 2A, a channel region 225 may be a region of a semiconductor material, between the first and second S/D regions 224 of the transistor 222, in which a channel of the transistor 222 forms during operation of the transistor 222. In general, the channel region 225 may be composed of semiconductor material systems including, for example, N-type or P-type materials systems. In some embodiments, the channel region 225 may include a substantially monocrystalline semiconductor, such as silicon (Si) or germanium (Ge). In some embodiments, the channel region 225 may include a compound semiconductor with a first sub-lattice of at least one element from group III of the periodic table (e.g., Al, Ga, In), and a second sub-lattice of at least one element of group V of the periodic table (e.g., P, As, Sb). In some embodiments, the channel region 225 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel region 225 may include a combination of semiconductor materials.

For some example N-type transistor embodiments (i.e., for the embodiments where a transistor 222 is an N-type metal-oxide-semiconductor (NMOS) transistor), the channel region 225 may include a Ill-V material having a relatively high electron mobility, such as, but not limited to InGaAs, InP, InSb, and InAs. For some such embodiments, the channel region 225 may be a ternary III—V alloy, such as InGaAs, GaAsSb, InAsP, or InPSb. For some InₓGa₁₋ₓ As fin embodiments, In content (x) may be between 0.6 and 0.9, and may advantageously be at least 0.7 (e.g., In_{0.7}Ga_{0.3}As). For some example P-type transistor embodiments (i.e., for the embodiments where a transistor 222 is a P-type metal-oxide-semiconductor (PMOS) transistor), the channel region 225 may advantageously be a group IV material having a high hole mobility, such as, but not limited to Ge or a Ge-rich SiGe alloy. For some example embodiments, the channel region 225 may have a Ge content between 0.6 and 0.9, and advantageously may be at least 0.7.

In some embodiments, the channel region 225 may be a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the channel region 225 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc.

As noted above, the channel region 225 may include IGZO. IGZO-based devices have several desirable electrical and manufacturing properties. IGZO has high electron mobility compared to other semiconductors, e.g., in the range of 20-50 times than amorphous silicon. Furthermore, amorphous IGZO (a-IGZO) transistors are typically characterized by high band gaps, low-temperature process compatibility, and low fabrication cost relative to other semiconductors. IGZO can be deposited as a uniform amorphous phase while retaining higher carrier mobility than oxide semiconductors such as zinc oxide. Different formulations of IGZO include different ratios of indium oxide, gallium oxide, and zinc oxide. One particular form of IGZO has the chemical formula InGaO₃(ZnO)₅. Another example form of IGZO has an indium:gallium:zinc ratio of 1:2:1. In various other examples, IGZO may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10). IGZO can also contain tertiary dopants such as aluminum or nitrogen.

In some embodiments, a transistor 222 may be a thin-film transistor (TFT). A TFT is a special kind of a field-effect transistor (FET) made by depositing a thin film of an active semiconductor material over a support (e.g., a support structure as described above) that may be a non-conducting support. Some such materials may be deposited at relatively low temperatures, which allows depositing them within the thermal budgets to avoid damaging other components such as the logic devices of an IC structure. At least a portion of the active semiconductor material forms a channel of the TFT. In some such embodiments, the channel region 225 may be a semiconductor material deposited at relatively low temperatures and may include any of the oxide semiconductor materials described above.

In other embodiments, instead of having semiconductor materials deposited at relatively low temperatures as described above with reference to the TFTs, the channel region 225 may include one or more semiconductor materials that are epitaxially grown in what typically involves relatively high-temperature processing. In such embodiments, the channel region 225 may include any of the semiconductor materials described above, including oxide semiconductor materials. In some such embodiments, the channel region 225 may be a semiconductor material epitaxially grown directly on a semiconductor layer of the substrate 210, in a process known as “monolithic integration.” In other such embodiments, the channel region 225 may be a semiconductor material epitaxially grown on a semiconductor layer of another support structure and then the epitaxially grown layer of the channel region 225 may be transferred, in a process known as a “layer transfer,” to the substrate 210, in which case the substrate 210 may but does not have to include a semiconductor layer prior to the layer transfer. Layer transfer advantageously allows forming transistors over support structures or in layers that do not include semiconductor materials (e.g., in the backend of an IC device). Layer transfer also advantageously allows forming transistors of any architecture (e.g., non-planar or planar transistors) without imposing the negative effects of the relatively high-temperature epitaxial growth process on devices that may already be present over a support structure.

The semiconductor material of the channel region 225 that is deposited at relatively low temperatures is typically a polycrystalline, polymorphous, or amorphous semiconductor, or any combination thereof. The semiconductor material of the channel region 225 that is epitaxially grown is typically a highly crystalline (e.g., monocrystalline, or single-crystalline) material. Therefore, whether the semiconductor material of the channel region 225 is deposited at relatively low temperatures or epitaxially grown can be identified by inspecting grain size of the active portions of the channel region 225. An average grain size of the semiconductor material of the channel region 225 being between about 0.5 and 1 millimeters (in which case the material may be polycrystalline) or smaller than about 0.5 millimeter (in which case the material may be polymorphous or amorphous) may be indicative of the semiconductor material of the channel region 225 having been deposited using a low-temperature process. On the other hand, an average grain size of the semiconductor material of the channel region 225 being equal to or greater than about 1 millimeter (in which case the material may be a single-crystal material) may be indicative of the semiconductor material of the channel region 225 having been epitaxially grown and included in the IC structure either by monolithic integration or by layer transfer.

The S/D regions 224 may be formed within the substrate 210 adjacent to the gate 226 of each transistor 222, on either side of the channel region 225, using any suitable processes known in the art. For example, the S/D regions 224 may be formed using either an implantation/diffusion process or a deposition process. In the former process, dopants such as boron, aluminum, antimony, phosphorous, or arsenic may be ion-implanted into the substrate 210 to form the S/D regions 224. An annealing process that activates the dopants and causes them to diffuse farther into the substrate 210 may follow the ion implantation process. In the latter process, an epitaxial deposition process may provide material that is used to fabricate the S/D regions 224. In some implementations, the S/D regions 224 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 224 may be formed using one or more alternate semiconductor materials such as germanium or a group III-V material or alloy. In further embodiments, one or more layers of metal and/or metal alloys may be used to form the S/D regions 224. In some embodiments, an etch process may be performed before the epitaxial deposition to create recesses in the substrate 210 in which the material for the S/D regions 224 is deposited.

Each transistor 222 may include a gate 226 that includes a gate electrode material 227 and, in some embodiments, a gate insulator 229.

The gate electrode material 227 may include a P-type workfunction metal or N-type workfunction metal, depending on whether the transistor 222 is to be a PMOS or an NMOS transistor, respectively. In some implementations, the gate electrode material 227 may include a stack of two or more metal layers, where one or more metal layers are workfunction metal layers and at least one metal layer is a fill metal layer. Further metal layers may be included for other purposes, such as a barrier layer or/and an adhesion layer. For a PMOS transistor, metals that may be used for the gate electrode material 227 include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 electron Volts (eV) and about 5.2 eV. For an NMOS transistor, metals that may be used for the gate electrode material 227 include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer will enable the formation of an NMOS gate electrode with a workfunction that is between about 3.9 eV and about 4.2 eV.

In some embodiments, when viewed as a cross-section of the transistor 222 along the source-channel-drain direction, the gate electrode material 227 may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode material 227 may be formed as a combination of U-shaped structures and planar, non-U-shaped structures. For example, the gate electrode material 227 may be implemented as one or more U-shaped metal layers formed atop one or more planar, non-U-shaped layers. In some embodiments, the gate electrode material 227 may be a V-shaped structure (e.g., when a fin of a FinFET transistor does not have a “flat” upper surface, but instead has a rounded peak).

In some embodiments, the gate insulator 229 may include one or more high-k dielectrics, e.g., insulator materials including elements such as hafnium, silicon, oxygen, titanium, tantalum, lanthanum, aluminum, zirconium, barium, strontium, yttrium, lead, scandium, niobium, and zinc. Examples of high-k materials that may be used for this purpose may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the gate insulator 229 during fabrication of the IC structures to improve the quality of the gate insulator 229. The gate insulator 229 may have a thickness that may, in some embodiments, be between about 0.5 nanometers and 10 nanometers, including all values and ranges therein (e.g., between about 0.5 and 3 nanometers, between about 1 and 3 nanometers, or between about 1 and 2 nanometers).

In some embodiments, e.g., when the transistor 222 is a storage transistor of a hysteretic memory cell (i.e., a type of memory that functions based on the phenomenon of hysteresis), the gate insulator 229 may be replaced with, or complemented by, a hysteretic material or a hysteretic arrangement, which, together, may be referred to as a “hysteretic element.” Transistors in which the gate insulator 229 includes a hysteretic element may be described as “hysteretic transistors” and may be used to implement hysteretic memory. Hysteretic memory refers to a memory technology employing hysteretic materials or arrangements, where a material or an arrangement may be described as hysteretic if it exhibits the dependence of its state on the history of the material (e.g., on a previous state of the material). Ferroelectric (FE) and antiferroelectric (AFE) materials are one example of hysteretic materials. Layers of different materials arranged in a stack to exhibit charge-trapping phenomena is one example of a hysteretic arrangement.

A FE or an AFE material is a material that exhibits, over some range of temperatures, spontaneous electric polarization, i.e., displacement of positive and negative charges from their original position, where the polarization can be reversed or reoriented by application of an electric field. In particular, an AFE material is a material that can assume a state in which electric dipoles from the ions and electrons in the material may form a substantially ordered (e.g., substantially crystalline) array, with adjacent dipoles being oriented in opposite (antiparallel) directions (i.e., the dipoles of each orientation may form interpenetrating sub-lattices, loosely analogous to a checkerboard pattern), while a FE material is a material that can assume a state in which all of the dipoles point in the same direction. Because the displacement of the charges in FE and AFE materials can be maintained for some time even in the absence of an electric field, such materials may be used to implement memory cells. Because the current state of the electric dipoles in FE and AFE materials depends on the previous state, such materials are hysteretic materials. Memory technology where logic states are stored in terms of the orientation of electric dipoles in (i.e., in terms of polarization of) FE or AFE materials is referred to as “FE memory,” where the term “ferroelectric” is said to be adopted to convey the similarity of FE memories to ferromagnetic memories, despite the fact that there is typically no iron (Fe) present in FE or AFE materials.

A stack of alternating layers of materials that is configured to exhibit charge-trapping is an example of a hysteretic arrangement. Such a stack may include as little as two layers of materials, one of which is a charge-trapping layer (i.e., a layer of a material configured to trap charges when a voltage is applied across the material) and the other one of which is a tunnelling layer (i.e., a layer of a material through which the charge is to be tunneled to the charge-trapping layer). The tunnelling layer may include an insulator material such as a material that includes silicon and oxygen (e.g., silicon oxide), or any other suitable insulator. The charge-trapping layer may include a metal or a semiconductor material that is configured to trap charges. For example, a material that includes silicon and nitrogen (e.g., silicon nitride) may be used in/as a charge-trapping layer. Because the trapped charges may be kept in a charge-trapping arrangement for some time even in the absence of an electric field, such arrangements may be used to implement memory cells. Because the presence and/or the amount of trapped charges in a charge-trapping arrangement depends on the previous state, such arrangements are hysteretic arrangements. Memory technology where logic states are stored in terms of the amount of charge trapped in a hysteretic arrangement may be referred to as “charge-trapping memory.”

Hysteretic memories have the potential for adequate non-volatility, short programming time, low power consumption, high endurance, and high speed writing. In addition, hysteretic memories may be manufactured using processes compatible with the standard CMOS technology. Therefore, over the last few years, these types of memories have emerged as promising candidates for many growing applications.

In some embodiments, the hysteretic element of the gate insulator 229 may be provided as a layer of a FE or an AFE material. Such an FE/AFE material may include one or more materials that can exhibit sufficient FE/AFE behavior even at thin dimensions, such as an insulator material at least about 5%, e.g., at least about 7% or about 10%, of which is in an orthorhombic phase and/or a tetragonal phase (e.g., as a material in which at most about 95-90% of the material may be amorphous or in a monoclinic phase). For example, such materials may be based on hafnium and oxygen (e.g., hafnium oxides), with various dopants added to ensure sufficient amount of an orthorhombic phase or a tetragonal phase. Some examples of such materials include materials that include hafnium, oxygen, and zirconium (e.g., hafnium zirconium oxide (HfZrO, also referred to as HZO)), materials that include hafnium, oxygen, and silicon (e.g., silicon-doped (Si-doped) hafnium oxide), materials that include hafnium, oxygen, and germanium (e.g., germanium-doped (Ge-doped) hafnium oxide), materials that include hafnium, oxygen, and aluminum (e.g., aluminum-doped (Al-doped) hafnium oxide), and materials that include hafnium, oxygen, and yttrium (e.g., yttrium-doped (Y-doped) hafnium oxide). However, in other embodiments, any other materials which exhibit FE/AFE behavior at thin dimensions may be used as the hysteretic element and are within the scope of the present disclosure.

In other embodiments, the hysteretic element of the gate insulator 229 may be provided as a stack of alternating layers of materials that can trap charges. In some such embodiments, the stack may be a two-layer stack, where one layer is a charge-trapping layer and the other layer is a tunnelling layer. The tunnelling layer may include an insulator material such as a material that includes silicon and oxygen (e.g., silicon oxide), or any other suitable insulator. The charge-trapping layer may include an electrically conductive material such as a metal, or a semiconductor material, that is a charge-trapping material. In some embodiments, the charge-trapping layer may include a material that includes silicon and nitrogen (e.g., silicon nitride). In general, any material that has defects that can trap charge may be used in/as a charge-trapping material. Such defects are very detrimental to operation of logic devices and, therefore, typically, deliberate steps need to be taken to avoid presence of the defects. However, for memory devices, such defects may be desirable because charge-trapping may be used to represent different memory states of a memory cell. In some embodiments, the tunnelling layer may be omitted, and the hysteretic element of the gate insulator 229 may be provided as a charge-trapping material, e.g., a material that includes silicon and nitrogen (e.g., silicon nitride) or, more generally, any material that has defects that can trap charge.

In some embodiments of the hysteretic element being provided as a stack of alternating layers of materials that can trap charges, the stack may be a three-layer stack where an insulator material is provided on both sides of a charge-trapping layer. In such embodiments, a layer of an insulator material on one side of the charge-trapping layer may be referred to as a “tunnelling layer” while a layer of an insulator material on the other side of the charge-trapping layer may be referred to as a “field layer.”

In various embodiments of the hysteretic element being provided as a stack of alternating layers of materials that can trap charges, a thickness of each layer the stack may be between about 0.5 and 10 nanometers, including all values and ranges therein, e.g., between about 0.5 and 5 nanometers. In some embodiment of a three-layer stack, a thickness of each layer of the insulator material may be about 0.5 nanometers, while a thickness of the charge-trapping layer may be between about 1 and 8 nanometers, e.g., between about 2.5 and 7.5 nanometers, e.g., about 5 nanometers. In some embodiments, a total thickness of the hysteretic element provided as a stack of alternating layers of materials that can trap charges (i.e., a hysteretic arrangement) may be between about 1 and 10 nanometers, e.g., between about 2 and 8 nanometers, e.g., about 6 nanometers.

Electrical signals, such as power and/or input/output (I/O) signals, may be routed to and/or from the transistors 222 and other components of the device layer 220 through one or more metal layers 230 disposed on the device layer 220, illustrated in FIG. 2A as metal layers 230-1, 230-2, and 230-3. For example, electrically conductive features of the device layer 220 (e.g., the gate 226 and the S/D contacts 228) may be electrically coupled with the interconnect structures 232 of the metal layers 230. Although a particular number of metal layers 230 is depicted in FIG. 2A, embodiments of the present disclosure include IC devices having more or fewer metal layers than depicted. The one or more metal layers 230 may form a metallization stack 240 of the IC structure 200A. The metal layers 230 are examples of the metal layers 130 of the IC structure 100A, and the metallization stack 240 is an example of the metallization stack 140 of the IC structure 100A.

The interconnect structures 232, which may also be referred to as “backend interconnect structures” because they are in the metal layers 230 which are in the backend of the IC structure 200A, may be arranged within the metal layers 230 to route electrical signals according to a wide variety of designs (in particular, the arrangement is not limited to the particular configuration of interconnect structures 232 depicted in FIG. 2A). In some embodiments, the interconnect structures 232 may include conductive lines 232a and/or conductive vias 232b, formed of an electrically conductive material such as a metal. The conductive lines 232a may be arranged to route electrical signals in a direction of a plane that is substantially parallel with a surface of the substrate 210 upon which the device layer 220 is formed. For example, the conductive lines 232a may route electrical signals in a direction in and out of the page from the perspective of FIG. 2A. The conductive vias 232b may be arranged to route electrical signals in a direction of a plane that is substantially perpendicular to the surface of the substrate 210 upon which the device layer 220 is formed. In some embodiments, the conductive vias 232b may electrically couple conductive lines 232a of different metal layers 230 together.

A first metal layer 230-1 (referred to as Metal 1 or “M1”) may be formed directly on the device layer 220. In some embodiments, the first metal layer 230-1 may include conductive lines 232a and/or conductive vias 232b, as shown. The conductive lines 232a of the first metal layer 230-1 may be coupled with contacts (e.g., the S/D contacts 228) of the device layer 220.

A second metal layer 230-2 (referred to as Metal 2 or “M2”) may be formed directly on the first metal layer 230-1. In some embodiments, the second metal layer 230-2 may include conductive vias 232b to couple the conductive lines 232a of the second metal layer 230-2 with the conductive lines 232a of the first metal layer 230-1. Although the conductive lines 232a and the conductive vias 232b are structurally delineated with a line within each metal layer (e.g., within the second metal layer 230-2) for the sake of clarity, the conductive lines 232a and the conductive vias 232b may be structurally and/or materially contiguous (e.g., simultaneously filled during a dual-damascene process) in some embodiments.

A third metal layer 230-3 (referred to as Metal 3 or “M3”) (and additional metal layers, as desired) may be formed in succession on the second metal layer 230-2 according to similar techniques and configurations described in connection with the second metal layer 230-2 or the first metal layer 230-1.

The metal layers 230 may include an insulator material 234 disposed between the interconnect structures 232, as shown in FIG. 2A. The insulator material 234 may take the form of any of the embodiments of the insulator materials provided between the interconnects of IC structures, for example any of the embodiments discussed herein with reference to the insulating medium of the metallization stack 140. In some embodiments, the insulator material 234 disposed between the interconnect structures 232 in different ones of the metal layers 230 may have different compositions. In other embodiments, the composition of the insulator material 234 in different metal layers 230 may be the same.

The IC structure 200A may include a solder resist material 236 (e.g., polyimide or similar material) and one or more conductive contacts 238 (e.g., bond pads) formed on the metal layers 230. The conductive contacts 238 may be electrically coupled with the interconnect structures 232 and configured to route the electrical signals of the transistor(s) 222 to other external devices. For example, solder bonds may be formed on the one or more conductive contacts 238 to mechanically and/or electrically couple a chip including the IC structure 200A with another component (e.g., a circuit board). The IC structure 200A may have other alternative configurations to route the electrical signals from the metal layers 230 than depicted in other embodiments. For example, the conductive contacts 238 illustrated in FIG. 2A as bond pads may be replaced by or may further include other analogous features (e.g., posts) that route the electrical signals to external components.

In some embodiments, any of the metal layers 230 and/or the device layer 220 may include one or more capacitors with porous materials, e.g., as a part of capacitor banks, as described herein. An example result of this is shown in FIG. 2A with a first capacitor bank 242-1 in the first metal layer 230-1 and a second capacitor bank 242-2 in the second metal layer 230-2. Although a particular number of capacitor banks 242 is depicted in FIG. 2A, embodiments of the present disclosure include IC devices having more or fewer capacitor banks 242 than depicted. The capacitor banks 242 may be arranged within the metal layers 230 to serve as capacitors for power delivery according to a wide variety of designs (in particular, the arrangement is not limited to the particular configuration of capacitor banks 242 depicted in FIG. 2A). In some embodiments, capacitor banks 242 may be fabricated as metal-insulator-metal (MIM) capacitors formed as part of the BEOL damascene processing. Although FIG. 2A illustrates individual capacitor banks 242 in respective metal layers 230, in some embodiments, one or more of the capacitor banks 242 may span multiple metal layers 230 (i.e., a single capacitor bank 242 may extend vertically as to have portions in multiple metal layers 230). Furthermore, in some embodiments, one or more of the capacitor banks 242 may span a device layer 220 and one or more metal layers 230 (i.e., a single capacitor bank 242 may extend vertically as to have portions in the device layer 220 and in one or more metal layers 230 adjacent to the device layer 220).

FIG. 1B illustrates a cross-sectional view of an example IC structure 100B in which one or more capacitor banks may be implemented, according to some embodiments of the present disclosure, and one example implementation of the IC structure 100B is an IC structure 200B shown in FIG. 2B, according to some embodiments of the present disclosure.

The IC structure 100B is similar to the IC structure 100A in that it may include the substrate 110, the device layer 120, and the metallization stack 140 comprising the metal layers 130, as described above. In addition, as shown in FIG. 1B, the IC structure 100B further includes a device layer 150 and metal layers 160, individually labeled as a metal layer 160-1 through metal layer 160-M, where M is an integer equal to or greater than 1 and may, but does not have to be, equal to N. Together, the metal layers 160 may be referred to as a metallization stack 170. The side of the substrate 110 on which the device layer 120 is provided is typically referred to as a front side, and the other side of the substrate 110 is referred to as a back side. Thus, the device layer 120 and the metal layers 130 are frontside layers, while the device layer 150 and the metal layers 160 are backside layers. As shown in FIG. 1B, the substrate 110 may be between the device layer 120 on the front side and the device layer 150 on the back side, the device layer 120 may be between the substrate 110 and the metallization stack 140, and the device layer 150 may be between the substrate 110 and the metallization stack 170.

Similar to the device layer 120, the device layer 150 may include any combination of components (e.g., ICs) provided over the back side of the substrate 110. For example, in some embodiments, the device layer 150 may include various logic layers, circuits, and devices (e.g., logic transistors) to drive and control a logic IC. In some embodiments, the device layer 150 may include memory devices/circuits. The device layer 150 may also be referred to as a “backside device layer” and the components of the device layer 150 (e.g., transistors) may be referred to as “backside components.” Other descriptions provided with respect to the device layer 120 are applicable to the device layer 150 and, in the interest of brevity, are not repeated. Various layers of the metallization stack 170 may be, or include, BEOL layers on the back side of the substrate 110, which may also be referred to as “backside backend layers.” Other descriptions provided with respect to the metal layers 130 and the metallization stack 140 are applicable to, respectively, the metal layers 160 and the metallization stack 170 and, in the interest of brevity, are not repeated.

FIG. 2B illustrates a cross-sectional side view of an example IC structure 200B that may include one or more capacitor banks in accordance with any of the embodiments disclosed herein. The IC structure 200B shown in FIG. 2B is an example of the IC structure 100B of FIG. 1B. As shown in FIG. 2B, the IC structure 200B is similar to the IC structure 200A in that it may include the substrate 210, and, at the front side of the IC structure 200B, further include the device layer 220, and the metallization stack 240 comprising the metal layers 230 with the interconnect structures 232, as described above. In addition, as shown in FIG. 2B, the IC structure 200B may further include one or more device layers 250 disposed on the back side of the IC structure 200B, e.g., on the back side of the substrate 210, where, together, the one or more device layers 250 may be an example of the device layer 150 of the IC structure 100B. Similar to the device layer 220, the device layer 250 may include features of one or more transistors 222 (e.g., MOSFETs) but formed on the back side of the substrate 210, e.g., channel regions/portions of the transistors 222 may be portions of the lowermost layers of the substrate 210. Other descriptions provided with respect to the transistors 222 in the device layer 220 are applicable to the transistors 222 in the device layer 250 at the back side of the IC structure 200B and, in the interest of brevity, are not repeated.

Electrical signals, such as power and/or input/output (I/O) signals, may be routed to and/or from the transistors 222 and other components of the device layer 220 and/or of the device layer 250 through one or more metal layers 260 disposed at the back side of the substrate 210, e.g., over the device layer 250, illustrated in FIG. 2B as metal layers 260-1, 260-2, and 260-3. For example, electrically conductive features of the device layer 220 (e.g., the gate 226 and the S/D contacts 228) and/or of the device layer 250 may be electrically coupled with the interconnect structures 262 of the metal layers 260. Although a particular number of metal layers 260 is depicted in FIG. 2B, embodiments of the present disclosure include IC devices having more or fewer metal layers than depicted. The one or more metal layers 260 may form a metallization stack 270 of the IC structure 200B. The metal layers 260 are examples of the metal layers 160 of the IC structure 100B, and the metallization stack 270 is an example of the metallization stack 170 of the IC structure 100B.

The interconnect structures 262, which may also be referred to as “backside interconnect structures” because they are in the metal layers 260 which are at the back side of the IC structure 200B, may be arranged within the metal layers 260 to route electrical signals according to a wide variety of designs (in particular, the arrangement is not limited to the particular configuration of interconnect structures 262 depicted in FIG. 2B). In some embodiments, the interconnect structures 262 may include conductive lines 262a and/or conductive vias 262b, formed of an electrically conductive material such as a metal. Descriptions provided with respect to the metal layers 230, the interconnect structures 232, the conductive lines 232a, and the conductive vias 232b at the front side of the IC structure 200B are applicable to, respectively, the metal layers 260, the interconnect structures 262, the conductive lines 262a, and the conductive vias 262b at the back side of the IC structure 200B and, in the interest of brevity, are not repeated.

The metal layers 260 at the back side of the IC structure 200B may include an insulator material 264 disposed between the interconnect structures 262, as shown in FIG. 2B. The IC structure 200B may include a solder resist material 266 (e.g., polyimide or similar material) and one or more conductive contacts 268 (e.g., bond pads) formed on the metal layers 260. Descriptions provided with respect to the insulator material 234, the solder resist material 236, and the conductive contacts 238 at the front side of the IC structure 200B are applicable to, respectively, the insulator material 264, the solder resist material 266, and the conductive contacts 268 at the back side of the IC structure 200B and, in the interest of brevity, are not repeated.

In some embodiments, any of the metal layers 260 and/or the device layer 250 may include one or more capacitor banks as described herein. An example result of this is shown in FIG. 2B with a first capacitor bank 272-1 in the first metal layer 260-1 and a second capacitor bank 272-2 in the second metal layer 260-2. Although a particular number of capacitor banks 272 is depicted in FIG. 2B, embodiments of the present disclosure include IC devices having more or fewer capacitor banks 272 than depicted. The capacitor banks 272 may be arranged within the metal layers 260 to serve as capacitors for power delivery from the back side of the IC structure 200B according to a wide variety of designs (in particular, the arrangement is not limited to the particular configuration of capacitor banks 272 depicted in FIG. 2B). In some embodiments, capacitor banks 272 may be fabricated as MIM capacitors formed as part of the BEOL damascene processing. Although FIG. 2B illustrates individual capacitor banks 272 in respective metal layers 260, in some embodiments, one or more of the capacitor banks 272 may span multiple metal layers 260 (i.e., a single capacitor bank 272 may extend vertically as to have portions in multiple metal layers 260). Furthermore, in some embodiments, one or more of the capacitor banks 272 may span a device layer 250 and one or more metal layers 260 (i.e., a single capacitor bank 272 may extend vertically as to have portions in the device layer 250 and in one or more metal layers 260 adjacent to the device layer 250). In various embodiments, the capacitor banks 272 may be coupled to (e.g., be in electrical contact with) one or more of the interconnect structures 262, one or more of the interconnect structures 232, and/or one or more of the terminals of the components of the device layer 220 (e.g., with one or more terminals of the transistors 222). As an example, FIG. 2B illustrates the 272-1 being coupled to one of the conductive vias 262b, but other drawings showing the capacitor banks 272 may include other arrangements and some of the capacitor banks 272 are not shown in the present drawings to be in contact with any other conductive structures or terminals of the devices of the device layer 220 because such connections may be made in planes other than the ones shown in the cross-sections of the present drawings.

The device layer 250 and the metal layers 260 may be monolithically integrated on the back side of the IC structure 200B, which is illustrated in FIG. 2B by, e.g., lack of a bonding layer or a bonding interface between the back side of the substrate 210 and the device layer 250. To that end, once the fabrication of various layers on the front side of the IC structure 200B has been completed, the IC structure 200B may be flipped upside down and fabrication of the device layer 250 and, subsequently, of the metal layers 260 may proceed in the similar manner but on the back side of the IC structure 200B. Further indicative of the monolithic integration, cross-sectional shapes (e.g., in a cross-section of the IC structure 200B in a plane substantially perpendicular to the device layer 220, such as the plane shown in FIG. 2B) of at least some of the interconnect structures 262 may be different from those of some of the interconnect structures 232. In particular, as shown in FIG. 2B, the conductive vias 232b (i.e., the backend vias of the IC structure 200B) may have shapes that taper in a direction from the conductive vias 232b towards the substrate 210 or the device layer 220 (or, phrased differently, in a direction from the conductive contacts 238 towards the substrate 210 or the device layer 220). On the other hand, the conductive vias 262b (i.e., the backside vias of the IC structure 200B) may have shapes that taper in a direction from the conductive vias 262b towards the substrate 210 or the device layer 220 (or, phrased differently, in a direction from the conductive contacts 268 towards the substrate 210 or the device layer 220).

FIG. 1C illustrates a cross-sectional view of an example IC structure 100C in which one or more capacitor banks may be implemented, according to some embodiments of the present disclosure, and one example implementation of the IC structure 100C is an IC structure 200C shown in FIG. 2C, according to some embodiments of the present disclosure.

The IC structure 100C is similar to the IC structure 100B except that the IC structure 100C does not include the device layer 150 at the back side of the substrate 110. Instead, the metal layers 160 are provided directly over the back side of the substrate 110. Thus, as shown in FIG. 1C, the substrate 110 may be between the device layer 120 on the front side and the metal layers 160 on the back side, and, as in FIG. 1B, the device layer 120 may be between the substrate 110 and the metallization stack 140.

FIG. 2C illustrates a cross-sectional side view of an example IC structure 200C that may include one or more capacitor banks in accordance with any of the embodiments disclosed herein. The IC structure 200C shown in FIG. 2C is an example of the IC structure 100C of FIG. 1C. As shown in FIG. 2C, the IC structure 200C is similar to the IC structure 200B except that the IC structure 200C does not include the device layer 250 at the back side of the substrate 210. Instead, the metal layers 260 are provided directly over the back side of the substrate 210. Thus, as shown in FIG. 2C, the substrate 210 may be between the device layer 220 on the front side and the metal layers 260 on the back side, and, as in FIG. 2B, the device layer 220 may be between the substrate 210 and the metallization stack 240.

The metal layers 260 may be monolithically integrated on the back side of the IC structure 200C, which is illustrated in FIG. 2C by, e.g., lack of a bonding layer or a bonding interface between the back side of the substrate 210 and the metal layers 260. To that end, once the fabrication of various layers on the front side of the IC structure 200C has been completed, the IC structure 200C may be flipped upside down and fabrication of the metal layers 260 may proceed in the similar manner but on the back side of the IC structure 200C. Further indicative of the monolithic integration, cross-sectional shapes (e.g., in a cross-section of the IC structure 200C in a plane substantially perpendicular to the device layer 220, such as the plane shown in FIG. 2C) of at least some of the interconnect structures 262 may be different from those of some of the interconnect structures 232, with the differences being the same as those described with reference to the IC structure 200B and, in the interest of brevity, not repeated here.

FIG. 1D illustrates a cross-sectional view of an example IC structure 100D in which one or more capacitor banks may be implemented, according to some embodiments of the present disclosure, and one example implementation of the IC structure 100D is an IC structure 200D shown in FIG. 2D, according to some embodiments of the present disclosure.

The IC structure 100D is similar to the IC structure 100C except that, in the IC structure 100D, once all of the layers on the front side have been fabricated and the IC structure 100D has been flipped over to continue with fabrication of the metal layers 160 on the back side, the substrate 110 may be thinned (e.g., polished, etched, or otherwise removed) to the point that terminals of the components of the device layer 120 (e.g., S/D regions of the transistors in the device layer 120) may be contacted from the back side. The metal layers 160 may then be provided directly over the back side of the device layer 120. Thus, as shown in FIG. 1D, the substrate 110 may be substantially removed (but the portions of the substrate 110 in which the frontend devices of the device layer 120 were fabricated remain), and the device layer 120 may be between the metal layers 130 on the front side and the metal layers 160 on the back side.

FIG. 2D illustrates a cross-sectional side view of an example IC structure 200D that may include one or more capacitor banks in accordance with any of the embodiments disclosed herein. The IC structure 200D shown in FIG. 2D is an example of the IC structure 100D of FIG. 1D. As shown in FIG. 2D, the IC structure 200D is similar to the IC structure 200C except that the IC structure 200D does not include the substrate 210 below the device layer 250. Instead, the metal layers 260 are provided directly over the back side of the device layer 250. Thus, as shown in FIG. 2D, the device layer 220 may be between the metal layers 230 on the front side and the metal layers 260 on the back side.

The metal layers 260 may be monolithically integrated on the back side of the IC structure 200D, once the substrate 210 has been thinned, which is illustrated in FIG. 2D by, e.g., lack of a bonding layer or a bonding interface between the back side of the device layer 220 and the metal layers 260. To that end, once the fabrication of various layers on the front side of the IC structure 200D has been completed, the IC structure 200D may be flipped upside down, the substrate 210 may be thinned down, and fabrication of the metal layers 260 may proceed on the back side of the device layer 220 of the IC structure 200D. Further indicative of the monolithic integration, cross-sectional shapes (e.g., in a cross-section of the IC structure 200D in a plane substantially perpendicular to the device layer 220, such as the plane shown in FIG. 2D) of at least some of the interconnect structures 262 may be different from those of some of the interconnect structures 232, with the differences being the same as those described with reference to the IC structure 200B and, in the interest of brevity, not repeated here.

FIGS. 1A-1D and FIGS. 2A-2D illustrate example embodiments where the metal layers 160 and the metal layers 260 on the back side are provided by monolithic integration. In other embodiments, the metal layers 160 and the metal layers 260 on the back side may be provided using hybrid bonding of separate IC structures together, as shown in FIGS. 1E-1H and FIGS. 2E-2H. FIG. 1E-1H illustrate cross-sectional views of, respectively, example IC structures 100E-100H in which one or more capacitor banks may be implemented, according to some embodiments of the present disclosure. One example implementation of the IC structure 100E is an IC structure 200E shown in FIG. 2E, one example implementation of the IC structure 100F is an IC structure 200F shown in FIG. 2F, one example implementation of the IC structure 100G is an IC structure 200G shown in FIG. 2G, and one example implementation of the IC structure 100H is an IC structure 200H shown in FIG. 2H, according to some embodiments of the present disclosure.

In general, hybrid bonding is described herein with reference to the metal layers 160 being fabricated on a separate IC structure and then bonded to the back side of the substrate 110, e.g., using a bonding material. When the bottom side of the metal layers 160 is bonded to the back side of the substrate 110 (e.g., after a support over which the metal layers 160 are fabricated is thinned down), the bonding may be described to as “back-to-back” (b2b), an example of which is shown in FIG. 1E. When the top side of the metal layers 160 is bonded to the back side of the substrate 110, the bonding may be described to as “front-to-back” (f2b), an example of which is shown in FIG. 1F. Continuing with the designation of the individual metal layers 160 used herein, where the metal layer 160-1 is the one fabricated first (i.e., the metal layer that is below all other metal layers of the metal layers 160), FIG. 1E illustrates that the metal layer 160-1 is closest to the device layer 120 and the metal layer 160-M is farthest from the device layer 120, representing the b2b bonding. Analogously, FIG. 1F illustrates that the metal layer 160-M is closest to the device layer 120 and the metal layer 160-1 is farthest from the device layer 120, representing the f2b bonding.

As a result of performing hybrid bonding, a bonding interface 180 may be present in the final IC structures. In the IC structure 100E of FIG. 1E, the bonding interface 180 is present between a face of the metal layer 160-1 and a face (the back side) of the substrate 110 being bonded together. In the IC structure 100F of FIG. 1F, the bonding interface 180 is present between a face of the metal layer 160-M and a face (the back side) of the substrate 110 being bonded together.

In some embodiments, bonding of the back side of the substrate 110 and one of the metal layers metal layers 160 may be performing using insulator-insulator bonding, e.g., as oxide-oxide bonding, where an insulator material of the substrate 110 or an insulator material provided over the back side of the substrate 110 for the purposes of bonding is bonded to an insulator material of the one of the metal layers metal layers 160 being bonded to the back side of the substrate 110. In some embodiments, a bonding material may be present in between the faces that are bonded together (e.g., the bonding interface 180 in the IC structure 100E and the IC structure 100F may include a bonding material). To that end, the bonding material may be applied to the one or both faces that are to be bonded and then the faces are put together, possibly while applying a suitable pressure and heating up the assembly to a suitable temperature (e.g., to moderately high temperatures, e.g., between about 50 and 200 degrees Celsius) for a duration of time. In some embodiments, the bonding material may be an adhesive material that ensures attachment of the faces of different IC structures to one another. In some embodiments, the bonding material may be an etch-stop material. In some embodiments, the bonding material may be both an etch-stop material and have suitable adhesive properties to ensure attachment of the first and second IC structures to one another. In some embodiments, the bonding material may include silicon, nitrogen, and carbon, where the atomic percentage of any of these materials may be at least 1%, e.g., between about 1% and 50%, indicating that these elements are added deliberately, as opposed to being accidental impurities which are typically in concentration below about 0.1%. Having both nitrogen and carbon in these concentrations in addition to silicon is not typically used in conventional semiconductor manufacturing processes where, typically, either nitrogen or carbon is used in combination with silicon, and, therefore, could be a characteristic feature of the hybrid bonding. Using at the bonding interface 180 an etch-stop material that includes include silicon, nitrogen, and carbon, where the atomic percentage of any of these materials may be at least 1%, e.g., SiOCN, may be advantageous in terms that such a material may act both as an etch-stop material, and have sufficient adhesive properties to bond the back of the substrate 110 and one of the metal layers 160 together. In addition, using at the bonding interface 180 an etch-stop material that includes include silicon, nitrogen, and carbon, where the atomic percentage of any of these materials may be at least 1%, may be advantageous in terms of improving etch-selectivity of this material with respect to etch-stop materials that may be used in the layers provided over the front side of the substrate 110 and the metal layers 160 provided at the back side of the substrate 110.

In some embodiments, no bonding material may be used, but there will still be a bonding interface (e.g., the bonding interface 180 of the IC structures 100E or 100F) resulting from the bonding of one of the metal layers 160 and the back side of the substrate 110 to one another. Such a bonding interface may be recognizable as a seam or a thin layer in the microelectronic assembly, using, e.g., selective area diffraction (SED), even when the specific materials of the insulators of the one of the metal layers 160 and the back side of the substrate 110 that are bonded together may be the same, in which case the bonding interface would still be noticeable as a seam or a thin layer in what otherwise appears as a bulk insulator (e.g., bulk oxide) layer.

The IC structure 200E shown in FIG. 2E is an example of the IC structure 100E of FIG. 1E. As shown in FIG. 2E, the IC structure 200E is similar to the IC structure 200C except that the IC structure 200E further includes a bonding interface 280 between the back side of the substrate 110 and the metal layers 260, in particular, the metal layer 260-1. The bonding interface 280 may be an example of the bonding interface 180, described above. The presence of the bonding interface 280 may be one characteristic feature indicative of the hybrid bonding used to form the IC structure 200E. Another characteristic feature indicative of the hybrid bonding is that cross-sectional shapes (e.g., in a cross-section of the IC structure 200E in a plane substantially perpendicular to the device layer 220, such as the plane shown in FIG. 2E) of at least some of the interconnect structures 262 may be different from those of some of the interconnect structures 232, with the differences being the same as those described with reference to the IC structure 200B and, in the interest of brevity, not repeated here.

The IC structure 200F shown in FIG. 2F is an example of the IC structure 100F of FIG. 1F. As shown in FIG. 2F, the IC structure 200F is similar to the IC structure 200E except that, in the IC structure 200F, the order of the metal layers 260 is reversed compared to the IC structure 200E, and the bonding interface 280 is between the back side of the substrate 110 and the metal layer 260-3. The presence of the bonding interface 280 may be one characteristic feature indicative of the hybrid bonding used to form the IC structure 200F. Another characteristic feature indicative of the hybrid bonding is that cross-sectional shapes (e.g., in a cross-section of the IC structure 200F in a plane substantially perpendicular to the device layer 220, such as the plane shown in FIG. 2F) of at least some of the interconnect structures 262 may be similar to those of some of the interconnect structures 232. In particular, as shown in FIG. 2F, the conductive vias 232b (i.e., the backend vias of the IC structure 200F) may have shapes that taper in a direction from the conductive vias 232b towards the substrate 210 or the device layer 220 (or, phrased differently, in a direction from the conductive contacts 238 towards the substrate 210 or the device layer 220), and the conductive vias 262b (i.e., the backside vias of the IC structure 200F) may have shapes that taper in the same direction, i.e., in a direction from the conductive vias 262b away from the substrate 210 or the device layer 220 (or, phrased differently, in a direction opposite to the direction from the conductive contacts 268 towards the substrate 210 or the device layer 220).

In some embodiments, conductive interconnects may extend through the bonding interface 280 of the IC structures 200E and 200F, in order to provide electrical connectivity for power and/or signals between the interconnect structures 262 and/or the capacitor banks 272 of the metallization stack 270 and the interconnect structures 232 and/or the capacitor banks 242 of the metallization stack 240 and/or devices of the device layer 220. Example of this are illustrated as after-bonding conductive vias 282 shown in the IC structure 200E, where one of the after-bonding conductive vias 282 of the IC structure 200E extends between one of the conductive contacts 268, one of the capacitor banks 272 (in particular, the capacitor bank 272-2, as an example), and one of the conductive vias 232b, and where another one of the after-bonding conductive vias 282 of the IC structure 200E extends between one of the capacitor banks 272 (in particular, the capacitor bank 272-1, as an example), and one of the S/D regions 224 of one of the transistor 222 in the device layer 220. The after-bonding conductive vias 282 shown in FIG. 2E taper from the bottom of the IC structure 200E (e.g., from the conductive contacts 268) to the top of the IC structure 200E (e.g., towards the device layer 220), which may be indicative of the after-bonding conductive vias 282 being fabricated from the side of the metal layers 260 at the back side of the device layer 220 (e.g., from the side of the one of the metal layers 260 that is farthest away from the device layer 220). Other examples of after-bonding conductive vias 282 are shown in the 200F of FIG. 2F, where one of the after-bonding conductive vias 282 of the IC structure 200F extends between one of the conductive contacts 268, one of the capacitor banks 272 (in particular, the capacitor bank 272-1, as an example), and one of the conductive lines 262a, and one of after-bonding conductive vias 284 of the IC structure 200F extends between one of the conductive contacts 238 and one of the capacitor banks 272 (in particular, the capacitor bank 272-2, as an example). The after-bonding conductive via 282 shown in FIG. 2F is similar to those shown in FIG. 2E in that it also tapers from the bottom of the IC structure 200F (e.g., from the conductive contacts 268) to the top of the IC structure 200F (e.g., towards the device layer 220), which may be indicative of the after-bonding conductive vias 282 of the IC structure 200F being fabricated from the side of the metal layers 260 at the back side of the device layer 220. On the other hand, the after-bonding conductive via 284 shown in FIG. 2F tapers from the top of the IC structure 200F (e.g., from the conductive contacts 238) to the bottom of the IC structure 200F (e.g., towards the device layer 220), which may be indicative of the after-bonding conductive via 284 of the IC structure 200F being fabricated from the side of the metal layers 230 at the front side of the device layer 220. In various other embodiments, any combination of the after-bonding conductive vias 282 and after-bonding conductive vias 284, between any of the components of the IC structures 200E and 200F are possible and within the scope of the present disclosure, not necessarily as shown in FIGS. 2E and 2F.

The IC structures 100G and 100H, shown in, respectively, FIG. 1G and FIG. 1H, are similar to, respectively, the IC structures 100E and 100F, except that the substrate 110 is thinned and the bonding interface 180 is between the back side of the device layer 120 and one of the metal layers 160. All of the descriptions provided above with respect to bonding the back side of the substrate 110 and one of the metal layers 160 using the bonding interface 180 are applicable to bonding the back side of the device layer 120 and one of the metal layers 160 using the bonding interface 180 of the IC structures 100G and 100H and, in the interest of brevity, are not repeated here. Descriptions provided with respect to thinning of the substrate 110 provided above with reference to the IC structure 100D are also applicable to the IC structures 100G and 100H and, in the interest of brevity, are not repeated. Similarly, IC structures 200G and 200H, shown in, respectively, FIG. 2G and FIG. 2H, are similar to, respectively, the IC structures 200E and 200F, except that the substrate 210 is thinned and the bonding interface 280 is between the back side of the device layer 220 and one of the metal layers 260. All of the descriptions provided above with respect to bonding the back side of the substrate 210 and one of the metal layers 260 using the bonding interface 280 are applicable to bonding the back side of the device layer 220 and one of the metal layers 260 using the bonding interface 280 of the IC structures 200G and 200H and, in the interest of brevity, are not repeated. Descriptions provided with respect to thinning of the substrate 210 provided above with reference to the IC structure 200D are also applicable to the IC structures 200G and 200H and, in the interest of brevity, are not repeated.

In still further embodiments, a combination of monolithically integrated and hybrid-bonded metal layers may be implemented. FIGS. 11-1J and FIGS. 2I-2J illustrate example embodiments where the metal layers 160, 260 on the back side are provided by monolithic integration, but metal layers 190, 290 are hybrid-bonded, either to the back side (as shown in FIG. 1I and FIG. 2I) or to the front side (as shown in FIG. 1J and FIG. 2J). FIG. 1I-1J illustrate cross-sectional views of, respectively, example IC structures 100I and 100J in which one or more capacitor banks may be implemented, according to some embodiments of the present disclosure. One example implementation of the IC structure 100I is an IC structure 200I shown in FIG. 2I, and one example implementation of the IC structure 100J is an IC structure 200J shown in FIG. 2J, according to some embodiments of the present disclosure.

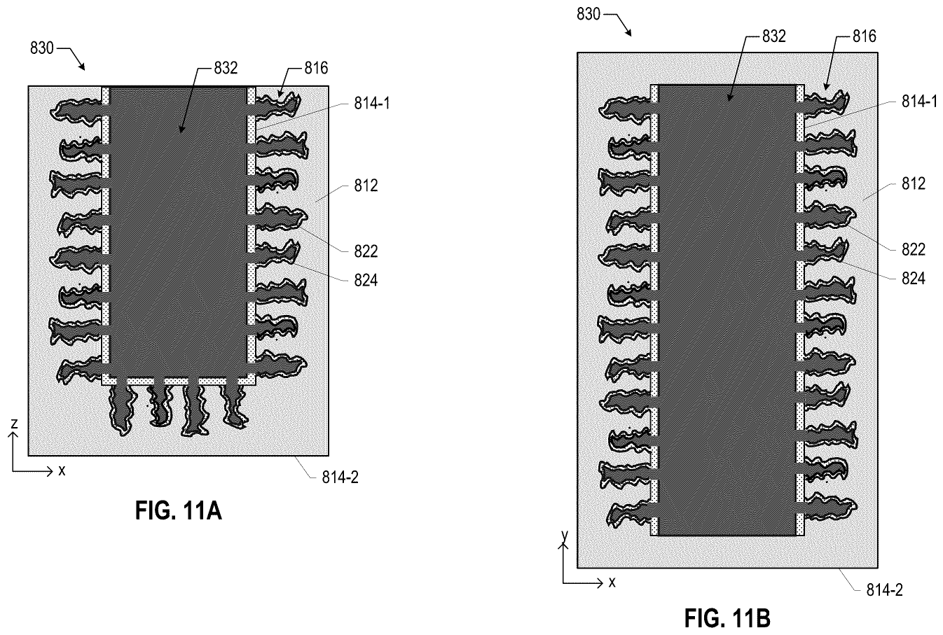

The IC structures 100I and 100J, shown in, respectively, FIGS. 11-1J, are similar to the IC structure 100C, except that they further include a bonding interface 180 and one more metal layers 190. In FIG. 1I, the bonding interface 180 and the one more metal layers 190 are on the back side of the device layer 120, e.g., the bonding interface 180 may be between the metal layer 160-M and the one more metal layers 190. In FIG. 1J, the bonding interface 180 and the one more metal layers 190 are on the front side of the device layer 120, e.g., the bonding interface 180 may be between the metal layer 130-N and the one more metal layers 190. All of the descriptions provided above with respect to bonding the one of the metal layers 160 using the bonding interface 180 are applicable to bonding the one more metal layers 190 as shown in FIGS. 1I and 1J and, in the interest of brevity, are not repeated here. The one more metal layers 190 may include structures (e.g., interconnects and/or capacitors) having a finer pitch than can be implemented in the metal layer 160-M if the one more metal layers 190 are bonded to the back side, or than can be implemented in the metal layer 130-N if the one more metal layers 190 are bonded to the front side of the device layer 120. In this manner, interconnects and/or capacitors with pitches smaller than those of metal layer underneath them may be implemented. Although FIGS. 1I and 1J illustrate the substrate 110 being present, as in the IC structure 100C of FIG. 1C, in other embodiments, the substrate 110 may be thinned and omitted from the IC structures 100I and 100J. In such embodiments, the IC structures 100I and 100J would be similar to the IC structure 100D of FIG. 1D, except that they further include a bonding interface 180 and one more metal layers 190 as described. Similarly, IC structures 2001 and 200J, shown in, respectively, FIGS. 2I-2J, are similar to the IC structure 200C, except that they further include a bonding interface 280 and one more metal layers 290 (individually shown as a metal layer 290-1 and a metal layer 290-2). The metal layers 290 are examples of the metal layers 190 of the IC structures 100I and 100J, and the bonding interface 280 is an example of the bonding interface 180 of the IC structures 100I and 100J. The metal layers 290 of FIGS. 2I-2J may include interconnect structures 292, arranged within the metal layers 290 to route electrical signals according to a wide variety of designs, as well as one of more after-bonding conductive vias 282 and/or 284, to route electrical signals from the metal layers 290 to the metal layers 260 and/or 230 according to a wide variety of designs (in particular, the arrangement is not limited to the particular configuration of interconnect structures 292 and after-bonding conductive vias 282 and/or 284 depicted in FIGS. 2I-2J).

In some embodiments, the interconnect structures 292 may include conductive lines 292a and/or conductive vias 292b, formed of an electrically conductive material such as a metal. The metal layers 290 may further include an insulator material 294 disposed between the interconnect structures 292. Descriptions provided with respect to the metal layers 260, the interconnect structures 262, the conductive lines 262a, the conductive vias 262b, and the insulator material 264 at the back side of the IC structure 200I are applicable to, respectively, the metal layers 290, the interconnect structures 292, the conductive lines 292a, the conductive vias 292b, and the insulator material 294 hybrid-bonded to the back side of the IC structure 200I or hybrid-bonded to the front side of the IC structure 200J and, in the interest of brevity, are not repeated.

An after-bonding conductive via 282 of the IC structure 200I and an after-bonding conductive via 284 of the IC structure 200J are examples of conductive interconnects may extend through the bonding interface 280 of the IC structures 2001 and 200J. Similar to those of the IC structures 200E and 200F, the after-bonding conductive vias 282, 284 extending through the bonding interface 280 may provide electrical connectivity for power and/or signals between the interconnect structures 292 and/or the capacitor banks 296 of the metal layers 290 on one side of the bonding interface 280 and any of the interconnect structures 232, the capacitor banks 242, the interconnect structures 262, or the capacitor banks 272 on the other side of the bonding interface 280. The after-bonding conductive vias 282 shown in FIG. 2I taper from the bottom of the IC structure 200I (e.g., from the conductive contacts 268) to the top of the IC structure 200I (e.g., towards the device layer 220), which may be indicative of the after-bonding conductive vias 282 being fabricated from the side of the metal layers 290 at the back side of the device layer 220 (e.g., from the side of the one of the metal layers 290 that is farthest away from the device layer 220). On the other hand, the after-bonding conductive via 284 shown in FIG. 2J tapers from the top of the IC structure 200J (e.g., from the conductive contacts 238) to the bottom of the IC structure 200J (e.g., towards the device layer 220), which may be indicative of the after-bonding conductive via 284 of the IC structure 200J being fabricated from the side of the metal layers 290 at the front side of the device layer 220. In various other embodiments, any combination of the after-bonding conductive vias 282 and after-bonding conductive vias 284, between any of the components of the IC structures 2001 and 200J are possible and within the scope of the present disclosure, not necessarily as shown in FIGS. 21 and 2J.

As shown in FIG. 2I, the IC structure 200I may include a solder resist material 266 (e.g., polyimide or similar material) and one or more conductive contacts 268 (e.g., bond pads) formed on the metal layers 290. As shown in FIG. 2J, the IC structure 200J may include a solder resist material 236 (e.g., polyimide or similar material) and one or more conductive contacts 238 (e.g., bond pads) formed on the metal layers 290. The IC structures 2001 and 200J further illustrate that one or more capacitor banks 296 may be implemented in the metal layers 290. In some embodiments, one of the metal layers 290 that is closest to the bonding interface 280 (e.g., the metal layer 290-2 in the illustrations of FIGS. 2I-2J) may have interconnect structures 292 and/or capacitor banks 296 having a larger pitch than the next one of the metal layers 290 (e.g., the metal layer 290-1 in the illustrations of FIGS. 2I-2J). Thus, interconnect structures 292 and/or capacitor banks 296 having a relatively small pitch, e.g., a pitch between about 50 nanometers and about 150 nanometers, may, advantageously, be implemented relatively far away from the device layer 220 and further away than metal layers with larger pitches. For example, for the IC structure 200I, a pitch of the interconnect structures 292 and/or capacitor banks 296 in the metal layer 290-1 may be smaller than that of the interconnect structures 262 and/or capacitor banks 272 in the metal layers 260-2 or 260-3. Similarly, for the IC structure 200J, a pitch of the interconnect structures 292 and/or capacitor banks 296 in the metal layer 290-1 may be smaller than that of the interconnect structures 232 and/or capacitor banks 242 in the metal layers 230-2 or 230-3. Descriptions provided with respect to the capacitor banks 272 are applicable to the capacitor banks 296 and, in the interest of brevity, are not repeated.

FIGS. 3A-3D illustrate example cross-sectional side views of capacitors 300 that may be used in capacitor banks, e.g., in the capacitor banks 242, 272, or 296 of the IC structures described with reference to FIGS. 2A-2J, or in any combination of such IC structures, according to some embodiments of the present disclosure. Each of FIGS. 3A-3D illustrates a first capacitor electrode 302-1, a second capacitor electrode 302-2 (together referred to as “capacitor electrodes 302”), and a capacitor insulator 310 between (i.e., separating) the first capacitor electrode 302-1 and the second capacitor electrode 302-2. The capacitor electrodes 302 may include any suitable conductive materials, e.g., any of the conductive metals or metal alloys described herein, any suitable metal nitrides (e.g., transition metal nitrides), any suitable metal carbides (e.g., transition metal carbides), or any other conductive materials. The capacitor insulator 310 may include any suitable insulator materials, e.g., any of the low-k insulator materials described herein, or any of the insulator materials described with reference to the gate insulator 229, including any of the hysteretic materials/elements (e.g., FE/AFE and/or charge-trapping materials), described herein.

FIG. 3A illustrates an embodiment where a capacitor 300 may be a planar capacitor. As shown in FIG. 3A, in such embodiments, the capacitor 300 may include planar layers of the first capacitor electrode 302-1, the capacitor insulator 310, and the second capacitor electrode 302-2, stacked above one another.

FIG. 3B illustrates an embodiment where a capacitor 300 may be a trench or a via capacitor. As shown in FIG. 3B, in such embodiments, the first capacitor electrode 302-1 may be provided in a trench/via in an insulator medium (e.g., in the insulator material 234 or the insulator material 264, described above, not specifically shown in FIG. 3B in order to not clutter the drawing), e.g., lining the sidewalls and the bottom of the trench/via in the insulator medium. The capacitor insulator 310 may then be provided as a liner over the first capacitor electrode 302-1 within the trench/via, and the second capacitor electrode 302-2 may then be deposited to at least partially fill the remainder of the trench/via. As shown in FIG. 3B, if the capacitor 300 is a trench/via capacitor, in a cross-section perpendicular to the device layer 220 of an IC structure, the first capacitor electrode 302-1 may be U-shaped.

FIG. 3C illustrates an embodiment where a capacitor 300 may be a pillar capacitor. As shown in FIG. 3C, in such embodiments, the first capacitor electrode 302-1 may be provided as a pillar over an insulator medium (e.g., over the insulator material 234 or the insulator material 264, described above, not specifically shown in FIG. 3C in order to not clutter the drawing). The capacitor insulator 310 may then be deposited to line the sidewalls and the top of the pillar of the first capacitor electrode 302-1, and the second capacitor electrode 302-2 may then be deposited to line the sidewalls and the top of the pillar of the first capacitor electrode 302-1 lined with the capacitor insulator 310. As shown in FIG. 3C, if the capacitor 300 is a pillar capacitor, in a cross-section perpendicular to the device layer 220 of an IC structure, the second capacitor electrode 302-2 may have an inverted U-shape (e.g., inverted with respect to the U-shape of the first capacitor electrode 302-1 shown in FIG. 3B).

FIG. 3D illustrates an embodiment where a capacitor 300 may be a double-walled capacitor. As shown in FIG. 3D, in such embodiments, the first capacitor electrode 302-1 may be provided in a trench/via in an insulator medium (e.g., in the insulator material 234 or the insulator material 264, described above, not specifically shown in FIG. 3D in order to not clutter the drawing), e.g., lining the sidewalls and the bottom of the trench/via in the insulator medium, similar to the first capacitor electrode 302-1 shown in FIG. 3B. After that, some of the insulator medium may be removed around the first capacitor electrode 302-1 so that portions of the first capacitor electrode 302-1 deposited on the sidewalls of the trench/via become pillars having their sidewalls exposed. A capacitor insulator 310 may then be deposited to line the sidewalls and the tops of the first capacitor electrode 302-1, followed by the deposition of the second capacitor electrode 302-2 to line the portions lined with the capacitor insulator 310. As shown in FIG. 3D, if the capacitor 300 is a double-walled capacitor, in a cross-section perpendicular to the device layer 220 of an IC structure, the first capacitor electrode 302-1 may have an U-shape, and some portions of the second capacitor electrode 302-2 may have inverted U-shapes (e.g., inverted with respect to the U-shape of the first capacitor electrode 302-1 of the capacitor 300 of FIG. 3D).

FIGS. 3A-3D illustrate only some examples of the capacitors 300 that may be used in capacitor banks described herein, e.g., in the capacitor banks 242, 272, 296, or 400. In further embodiments, other capacitor architectures are possible and are within the scope of the present disclosure. For example, any of the capacitor banks described herein may include one or more capacitors with porous materials as described with reference to FIGS. 7-13. A choice of a particular capacitor architecture may depend on factors such as the capacitance to be realized, space available for implementing the capacitors (e.g., size and form factor may be critical in some implementations), level of complexity in the fabrication process, voltage rating of a capacitor, frequency response, parasitic effects, etc. For example, a capacitor 300 as shown in FIG. 3A may have advantages in terms of a relatively simple fabrication process, while capacitors 300 shown in FIGS. 3B-3D may be advantageous in terms in increased capacitance. Furthermore, a capacitor 300 as shown in FIG. 3D may be able to realize higher capacitance than the capacitors 300 shown in FIGS. 3B and 3C because of the double-walled architecture but may require additional masks and processing steps to fabricate. In some embodiments, a capacitor bank may include one or more capacitors such as the ones shown in FIGS. 3A-3D as well as one or more capacitors with porous materials as described with reference to FIGS. 7-13.

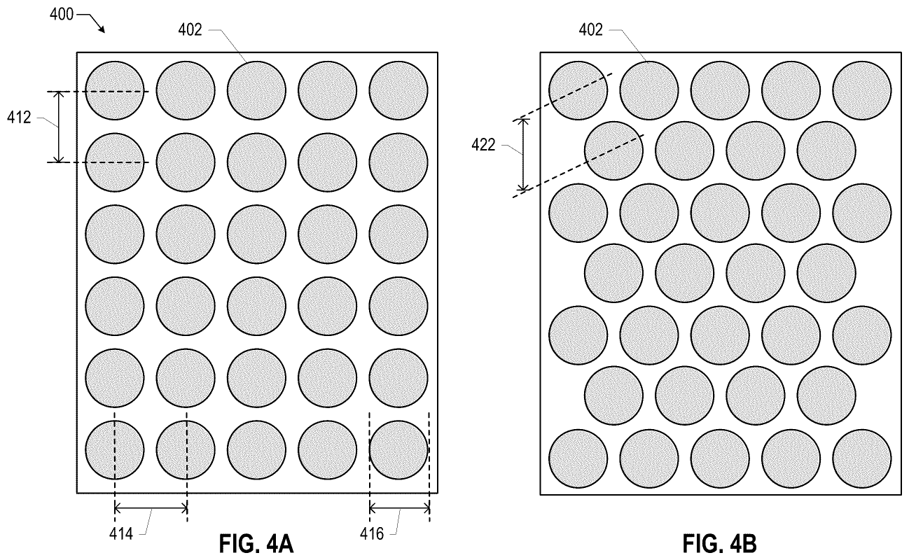

FIGS. 4A-4B provide schematic illustrations of example top-down views of capacitor banks 400, according to some embodiments of the present disclosure. Any of the capacitor banks 400 may be an example of one of the capacitor banks 242, 272, or 296 of the IC structures described with reference to FIGS. 2A-2J, or in any combination of such IC structures, according to some embodiments of the present disclosure. In FIGS. 4A-4B, individual capacitors of the capacitor banks 400 are shown as capacitors 402, represented by circles, although, in various embodiments, top-down views of the capacitors 402 that may be used in capacitor banks 400 may have shapes other than circles. Any of the capacitors 402 may be implemented as any of the capacitors 300 shown in FIGS. 3A-3D, any other capacitors known in the art, or any of the capacitors with porous materials as described with reference to FIGS. 7-13.

FIG. 4A illustrates a capacitor bank 400 where different capacitors 402 are arranged in a rectangular array of straight rows and columns. The capacitors 402 may have a first pitch (e.g., measured as a center-to-center distance) for different capacitors 402 in one column but belonging to different rows, labeled in FIG. 4A as a pitch 412. The capacitors 402 may have a second pitch (e.g., also measured as a center-to-center distance) for different capacitors 402 in one row but belonging to different columns, labeled in FIG. 4A as a pitch 414. The pitch 412 and the pitch 414 may, but do not have to be, substantially the same. In some embodiments, the pitch 412 and the pitch 414 may be between about 50 nanometers and about 150 nanometers. In other embodiments, the pitch 412 and the pitch 414 may be between about 500 nanometers and about 4 microns.

In some embodiments, the pitches 412 and 414 may be larger, e.g., between about 500 nanometers and about 4 microns, if the capacitor bank 400 is implemented in one of the metal layers 260 that are further away from the substrate over which the metal layers 260 are fabricated, and may be smaller, e.g., between about 50 nanometers and about 150 nanometers if the capacitor bank 400 is implemented in one of the metal layers 260 that are closer to the substrate over which the metal layers 260 are fabricated. For example, the pitches 412 and 414 of the capacitor bank 400 being used to implement the second capacitor bank 272-2 or the second capacitor bank 242-2, described above, may be larger than the pitches 412 and 414 of the capacitor bank 400 being used to implement the first capacitor bank 272-1 or the first capacitor bank 242-1 because the first capacitor banks 272-1 or 242-1 are fabricated before (i.e., closer to the substrate) fabricating the second capacitor banks 272-2 or 242-2, respectively. Inventors of the present disclosure realized that the specific range of a pitch between adjacent capacitors 402 of a capacitor bank 400 being between about 50 nanometers and about 150 nanometers may be particularly advantageous in terms of tight packing of the capacitors 402, e.g., if the capacitors 402 are implemented in lower-level metal layers of a metallization stack. Inventors of the present disclosure further realized that the specific range of the pitch being between about 500 nanometers and about 4 microns may be particularly advantageous in terms of the ability to implement larger capacitors 402, leading to larger overall capacitance of the capacitor bank 400.

In some embodiments, the pitches 412 and 414 may be smaller, e.g., between about 50 nanometers and about 150 nanometers, if the capacitor bank 400 is implemented in one of the metal layers 290 that are hybrid-bonded to the back side or to the front side of the device layer with other metal layers, e.g., as described with reference to FIGS. 2I-2J. In this manner, even though an IC structure may include a capacitor bank 400 with larger pitches 412 and 414, e.g., between about 500 nanometers and about 4 microns, closer to the device layer 220, it may further include another capacitor bank 400 with smaller pitches 412 and 414, e.g., between about 50 nanometers and about 150 nanometers, further away from the device layer 220. In this manner, larger numbers of tightly packed capacitors may be provided in the capacitor banks 400 implemented in a given IC structure.

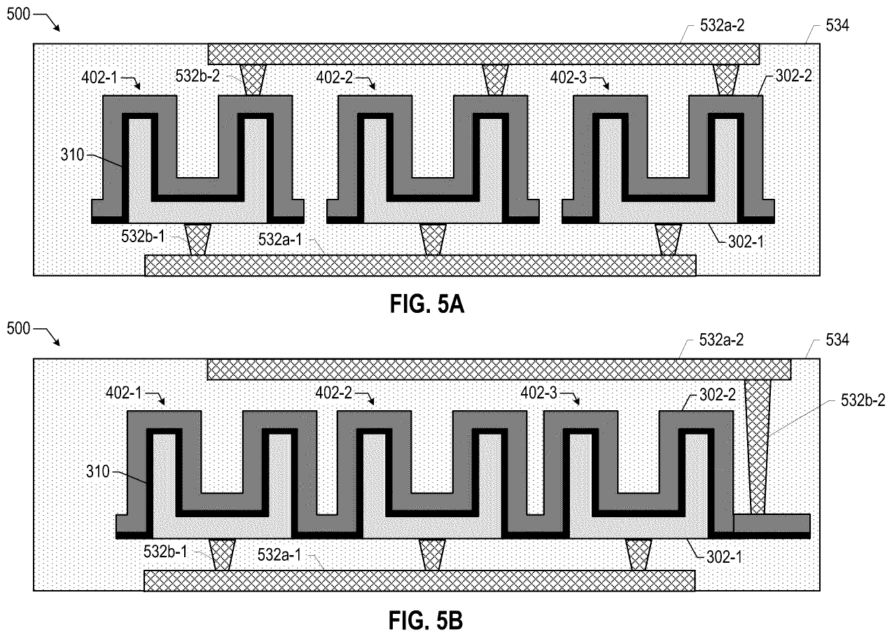

In some embodiments, an average width 416 of an individual one of the capacitors 402 may be up to about 90% of the pitch 412 and/or the pitch 414, if adjacent capacitors 402 of the capacitor bank 400 are not in contact with one another (e.g., as shown in FIG. 5A). However, in some embodiments, adjacent capacitors 402 of the capacitor bank 400 may be in contact with one another (e.g., as shown in FIG. 5B), in which case the width 416 of an individual one of the capacitors 402 may be about 100% (i.e., about the same) of the pitch 412 and/or the pitch 414. If the capacitors 402 are arranged in a square array, then each capacitor 402 that is not at the periphery of the capacitor bank 400 may have four nearest-neighbor capacitors 402 and four second-nearest-neighbor capacitors 402, as is shown in FIG. 4A.

FIG. 4B illustrates a capacitor bank 400 where different capacitors 402 are arranged in a hexagonal array, which may also be referred to as a honeycomb array. The capacitors 402 may have a pitch (e.g., measured as a center-to-center distance), labeled in FIG. 4B as a pitch 422. Descriptions provided for the pitches 412 and 414 are applicable to the pitch 422 and, in the interest of brevity, are not repeated. If the capacitors 402 are arranged in a hexagonal array, then each capacitor 402 that is not at the periphery of the capacitor bank 400 may have six nearest-neighbor capacitors 402, as is shown in FIG. 4B.

FIGS. 4A-4B illustrate only some examples of the capacitor banks 400 that may be used in capacitor banks described herein, e.g., in the capacitor banks 242, 272, or 296. In further embodiments, other arrangements of the individual capacitors 402 within a capacitor bank 400 are possible and are within the scope of the present disclosure. A choice of a particular arrangement of the individual capacitors 402 within a capacitor bank 400 may depend on factors such as the capacitance to be realized by the capacitor bank 400, space available for implementing the capacitor bank 400, level of complexity in the fabrication process, etc. For example, a capacitor bank 400 as shown in FIG. 4A may have advantages in terms of a relative simplicity of fabrication, alignment with grid-based systems, regularity in layout, compatibility with certain fabrication tools, etc. On the other hand, a capacitor bank 400 as shown in FIG. 4B may be advantageous in terms of more efficient space utilization (more dense packing of the capacitors 402), uniform distribution, increased structural stability, higher degree of symmetry, etc.

Within a given capacitor bank 400, the first capacitor electrodes of all of the capacitors 402 may be electrically connected to one another and to a single first control line, and the second capacitor electrodes of all of the capacitors 402 may be electrically connected to one another and to a single second control line. In this manner, multiple capacitors 402 of a capacitor bank 400 may be connected in parallel and act as a single capacitor, where the total capacitance of the capacitor bank 400 may be substantially equal to a sum of the capacitances of the individual capacitors 402. An example of this is illustrated in FIGS. 5A-5B, showing example cross-sectional side views of capacitor banks 500, where different capacitors are coupled to first and second conductive lines, according to some embodiments of the present disclosure. Individual capacitors are labeled in FIGS. 5A-5B as capacitors 402-1, 402-2, and 402-3, indicating that these capacitors may be examples of capacitors 402 of any of the capacitor banks 400 described herein. Thus, capacitor banks 500 shown in FIGS. 5A-5B are examples of the capacitor banks 400 described herein. The capacitors 402 are shown in FIGS. 5A-5B as double-walled capacitors 300 shown in FIG. 3D, where the first capacitor electrode 302-1, the second capacitor electrode 302-2, and the capacitor insulator 310 as described with reference to the capacitors 300 are shown in FIGS. 5A-5B. Thus, capacitor banks 500 shown in FIGS. 5A-5B are examples of the capacitor banks implementing capacitors 300 described herein, in particular implementing capacitors 300 as shown in FIG. 3D. However, descriptions of the capacitor banks 500 shown in FIGS. 5A-5B are applicable to capacitors of any other capacitor architectures.

FIG. 5A illustrates a capacitor bank 500 in which individual capacitors 402 are separated from one another in that their first capacitor electrodes 302-1 are not materially continuous with one another, their second capacitor electrodes 302-2 are not materially continuous with one another, and their capacitor insulators 310 are not materially continuous with one another. For example, an insulator material 534 may separate individual capacitors 402 from one another, as shown in FIG. 5A. In such embodiments, the first capacitor electrodes 302-1 of all of the capacitors 402 may be coupled to a first conductive line 532a-1, while the second capacitor electrodes 302-2 of all of the capacitors 402 may be coupled to a second conductive line 532a-2. For example, in some embodiments, a respective conductive via 532b-1 may be provided between (e.g., in electrical/physical contact with) the first capacitor electrode 302-1 of a given capacitor 402 and the first conductive line 532a-1, and a respective conductive via 532b-2 may be provided between (e.g., in electrical/physical contact with) the second capacitor electrode 302-2 of a given capacitor 402 and the second conductive line 532a-2, as shown in FIG. 5A. The first conductive line 532a-1 and the second conductive line 532a-2 may be examples of the conductive lines 232a or 262a, described above, depending on whether the capacitor bank 500 is implemented in the metallization stack 240 on the front side of the device layer 220 or in the metallization stack 270 on the back side of the device layer 220. Similarly, the first conductive via 532b-1 and the second conductive via 532b-2 may be examples of the conductive vias 232b or 262b, and the insulator material 534 may be an example of the insulator materials 234 or 264, described above, depending on whether the capacitor bank 500 is implemented in the metallization stack 240 on the front side of the device layer 220 or in the metallization stack 270 on the back side of the device layer 220.

FIG. 5B illustrates a capacitor bank 500 in which individual capacitors 402 have portions in contact with one another in that their second capacitor electrodes 302-2 are materially continuous with one another, and their capacitor insulators 310 are materially continuous with one another, as shown. Because a single layer of a conductive material serves as the second capacitor electrode 302-2 of all of the capacitors 402 of the capacitor bank 500 of FIG. 5B, a single conductive via 532b-2 may be provided between (e.g., in electrical/physical contact with) the second capacitor electrode 302-2 of all of the capacitors 402 and the second conductive line 532a-2, as shown. In some embodiments, placing the single conductive via 532b-2 at the periphery of the capacitor bank 500, as shown in FIG. 5B, may be particularly advantageous in terms of easier routing of the interconnects. In the capacitor bank 500 of FIG. 5B, the first capacitor electrodes 302-1 of different capacitors 402 are not materially continuous with one another, and, therefore, a respective conductive via 532b-1 may be provided between (e.g., in electrical/physical contact with) the first capacitor electrode 302-1 of a given capacitor 402 and the first conductive line 532a-1, similar to the arrangement of FIG. 5A.

While FIGS. 5A-5B illustrate that the first conductive line 532a-1 and the second conductive line 532a-2 are provided on opposite sides of the capacitors 402 (at the bottom and at the top, respectively), in other embodiments of the capacitor banks 500, the first conductive line 532a-1 and the second conductive line 532a-2 may be provided on the same side of the capacitors 402 (e.g., either both at the bottom of the capacitors 402 or both at the top of the capacitors 402).

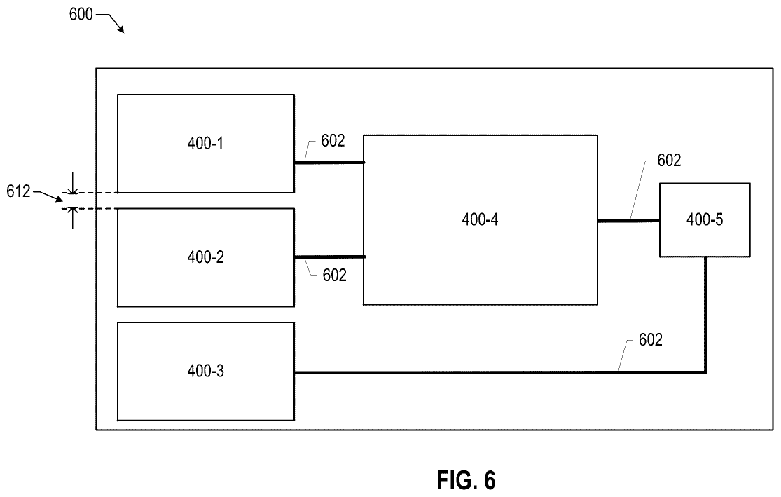

FIG. 6 provides a schematic illustration of an example top-down view of an IC structure 600 with multiple capacitor banks 400, shown individually as capacitor banks 400-1 through 400-5, according to some embodiments of the present disclosure. As shown in FIG. 6, in some embodiments, the IC structure 600 may include a plurality of capacitor banks 400 where at least some of the capacitor banks 400 may have different sizes (e.g., different footprints, as shown in FIG. 6 for the capacitor banks 400-1, 400-4, and 400-5). FIG. 6 further illustrates that some of the capacitor banks 400 may have sizes/footprints that are substantially the same (e.g., as shown in FIG. 6 for the capacitor banks 400-1, 400-2, and 400-3). In some embodiments, a distance between adjacent capacitor banks 400 (an example of which is shown as a distance 612 between the capacitor banks 400-1 and 400-2) may be between about twice the pitch of the individual capacitors within either one of the adjacent capacitor banks 400 and about 10 microns. In some embodiments, either the first capacitor electrodes of the capacitors 402 or the second capacitor electrodes of the capacitors 402 of one of the capacitor banks 400 may be electrically coupled (e.g., in conductive contact with) either the first capacitor electrodes of the capacitors 402 or the second capacitor electrodes of the capacitors 402 of another one of the capacitor banks 400. In this manner, two such capacitor banks may be connected in series. This is represented in FIG. 6 by showing conductive lines 602 between various pairs of the capacitor banks 400. For example a conductive line 602 may be coupled to either the first or the second capacitor electrodes of the capacitors 402 of the capacitor bank 400-1 and either the first or the second capacitor electrodes of the capacitors 402 of the capacitor bank 400-4, realizing a series connection between the capacitor bank 400-1 and the capacitor bank 400-4.

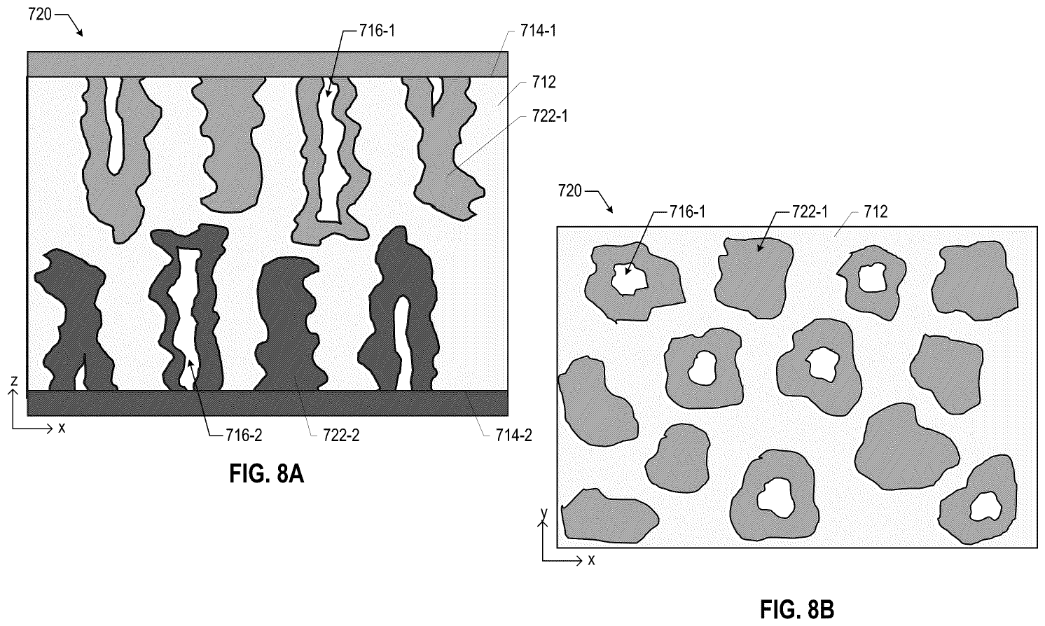

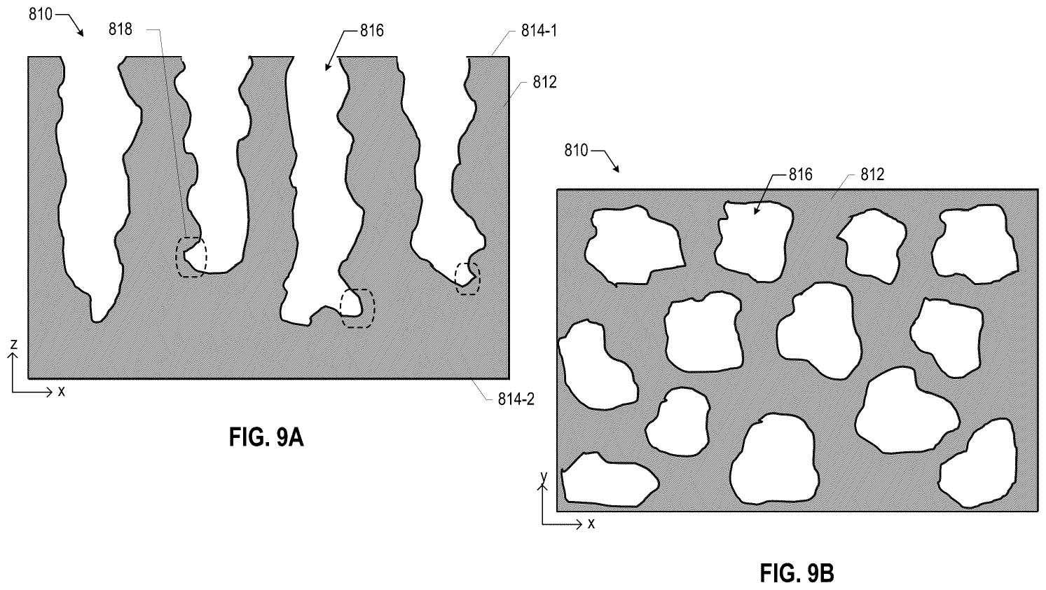

FIGS. 7-13 relate to capacitors with porous materials. In some embodiments, any of these capacitors may be one of the capacitors of one or more capacitors of the capacitor banks 242, 272, and 296, described above. In particular, FIGS. 7-8 relate to capacitors with a capacitor insulator being implemented as a porous material, while FIGS. 9-13 relate to capacitors with a capacitor electrode being implemented as a porous material. Each of FIGS. 7-13 include a figure A (e.g., FIG. 7A, 8A, 9A, and so on) and a figure B (e.g., FIG. 7B, 8B, 9B, and so on), where figure A provides a cross-sectional side view (e.g., in a plane x-z of the coordinate system 105) and figure B provides a top-down view (e.g., in a plane x-y of the coordinate system 105) of an IC structure.

FIGS. 7A-7B illustrate examples of a cross-sectional side view and a top-down view of an IC structure 710 after a first stage of fabrication of a capacitor with a porous material being used as a capacitor insulator, according to some embodiments of the present disclosure. As shown in FIGS. 7A-7B, the fabrication may begin with providing a structure of a porous insulator material 712, where the structure has a first side 714-1 a second side 714-2 opposite the first side 714-1. The insulator material 712 is a porous insulator material because it includes first pores 716-1 extending from the first side 714-1 towards, but not reaching, the second side 714-2, and further includes second pores 716-2 extending from the second side 714-2 towards, but not reaching, the first side 714-1 (where, together, the first pores 716-1 and the second pores 716-2 may be referred as “pores 716”).

In some embodiments, the porous insulator material 712 may include a semiconductor material and oxygen, e.g., an oxide of one or more of silicon, germanium, silicon germanium, etc., which makes the semiconductor material electrically insulative. In various embodiments, a semiconductor material may be made porous by various means, all of which being within the scope of the present disclosure.

For example, in some embodiments, the porous insulator material 712 may be provided by depositing a semiconductor material in multiple deposition stages and, after at least some of the deposition stages, etching the semiconductor material using, in an alternating manner, relatively strong and relatively weak etchants, which would result in creation of the pores 716. For example, if the semiconductor material is silicon, then a relatively strong etchant may be sulfur tetrafluoride (SF₄), which etches silicon relatively quickly, and a relatively weak etchant may be hydrogen fluoride (HF), which etches silicon relatively slowly. The porous insulator material 712 may then be provided by depositing a thin layer of a semiconductor material, then exposing the semiconductor material to either a relatively strong or a relatively weak etchant, depositing another thin layer of the semiconductor material, exposing the semiconductor material to the other one of the relatively strong or the relatively weak etchant, and so on, which would create the pores 716 in the semiconductor material. In other embodiments, the porous insulator material 712 may be provided by depositing a thin layer of a semiconductor material, oxidizing it, etching out the oxide, then deposing another layer of the semiconductor material, oxidizing it, etching out the oxide, and so on, which would create the pores 716 in the semiconductor material. In still further embodiments, the porous insulator material 712 may be provided by depositing a layer of a semiconductor material deliberately introducing irregularities at the surface, e.g., deliberately providing defects at the surface of the semiconductor material (e.g., using ion plasma etch or dopant implantation). The irregularities/defects may then be used to enhance either of the previous techniques to create etch-selective regions that may be used to create pores. In any of these embodiments, the semiconductor material with pores may be oxidized to make it electrically insulating, which could be done either after all of the semiconductor material with pores has been deposited or as it is being deposited.

In some embodiments, conditions for deposition of the porous insulator material 712 may be controlled to ensure that the pores 716 have sizes (e.g., widths and/or lengths) between about 5 nanometers and 20 nanometers, e.g., to ensure that none of the pores 716 have sizes greater than about 20 nanometers. In some embodiments, a thickness of the porous insulator material 712, e.g., a distance between the first side 714-1 and the second side 714-2, may be between about 2 nanometers and about 100 nanometers. In some embodiments, density of the pores 716 may be on the order of 10⁵ pores per cubic centimeter, e.g., at least 10¹⁵ pores per cubic centimeter or at least 10¹⁸ pores per cubic centimeter. In some embodiments, an area-to-volume ratio of the porous insulator material 712, which is a ratio between a surface area of the combined surface of all of the pores 716 in the porous insulator material 712 to the combined volume of all of the pores 716, may be relatively high. Any of the pores 716 may be irregularly shaped channels, i.e., the pores 716 are different from, e.g., via openings, etched in a material. In some embodiments, at least some of the pores 716 may have portions extending in a direction substantially parallel to the first side 714-1 or the second side 714-2, e.g., as shown in FIG. 7A with areas of the pores 716 within dotted contours 718.

FIGS. 8A-8B illustrate examples of a cross-sectional side view and a top-down view of an IC structure 720 after a second stage of fabrication of a capacitor with a porous material being used as a capacitor insulator, according to some embodiments of the present disclosure. The IC structure 720 is the same as the IC structure 710, except that it further includes a first conductive material 722-1 at least partially filling the first pores 716-1 and a second conductive material 722-2 at least partially filling the second pores 722-2 (where, together, the first conductive material 722-1 and the second conductive material 722-2 may be referred as “conductive materials 722”). Thus, as shown in FIGS. 8A-8B, the fabrication may continue with depositing the first conductive material 722-1 into the first pores 716-1 and depositing the second conductive material 722-2 into the second pores 716-2. The first conductive material 722-1 and the second conductive material 722-2 may include any suitable conductive materials, e.g., any of the conductive metals or metal alloys described herein, any suitable metal nitrides (e.g., transition metal nitrides), any suitable metal carbides (e.g., transition metal carbides), or any other conductive materials. The conductive materials 722 may be deposited using any suitable deposition technique, such as physical vapor deposition (PVD), chemical vapor deposition (CVD), atomic level deposition (ALD), electroplating, spin-coating, etc. As shown in FIG. 8A, the first conductive material 722-1 and the second conductive material 722-2 are separated from one another by the porous insulator material 712. In some embodiments, an average distance between closest portions of the first conductive material 722-1 and second conductive material 722-2 may be between about 1 nanometer and about 20 nanometers, e.g., between about 1 nanometer and about 15 nanometers, or between about 2 nanometers and about 5 nanometers. In some embodiments, the first conductive material 722-1 in various first pores 716-1 may be materially continuous with one another, e.g., by virtue of having a layer of the first conductive material 722-1 over the first side 714-1 of the porous insulator material 712, as shown in FIG. 8A. Similarly, in some embodiments, the second conductive material 722-2 in various second pores 716-2 may be materially continuous with one another, e.g., by virtue of having a layer of the second conductive material 722-2 over the second side 714-2 of the porous insulator material 712, as also shown in FIG. 8A. The IC structure 720 may, thus, provide a capacitor with a porous material, where the first conductive material 722-1 is a first capacitor electrode, the second conductive material 722-2 is a second capacitor electrode, and the porous insulator material 712 is a capacitor insulator.

FIGS. 9A-9B illustrate examples of a cross-sectional side view and a top-down view of an IC structure 810 after a first stage of fabrication of a capacitor with a porous material being used as a capacitor electrode, according to some embodiments of the present disclosure. As shown in FIGS. 9A-9B, the fabrication may begin with providing a structure of a porous semiconductor material 812, where the structure has a first side 814-1 a second side 814-2 opposite the first side 814-1. The semiconductor material 812 is a porous semiconductor material because it includes pores 816 extending from the first side 814-1 towards, but not reaching, the second side 814-2.

In some embodiments, the porous semiconductor material 812 may include a semiconductor material and one or more dopants to make the semiconductor material electrically conductive. For example, the semiconductor material may include one or more of silicon, germanium, silicon germanium, etc., while dopants may include P-type or N-type dopants (e.g., elements typically used to form S/D regions of transistors, e.g., as described above). In some embodiments, dopant concentration of the dopants in the porous semiconductor material 812 may be at least about 10¹⁸ dopants per cubic centimeter, e.g., at least about 10²⁰ dopants per cubic centimeter or at least about 10²¹ dopants per cubic centimeter. In various embodiments, a semiconductor material may be made porous by various means, e.g., some of those described above with reference to the porous insulator material 712, except that instead of making the semiconductor material electrically insulative to provide the porous insulator material 712, the porous semiconductor material may be made electrically conductive by adding dopants to provide the porous semiconductor material 812.

In some embodiments, conditions for deposition of the porous semiconductor material 812 may be controlled to ensure that the pores 816 have sizes (e.g., widths and/or lengths) between about 10 nanometers and 100 nanometers, e.g., to ensure that none of the pores 816 have sizes greater than about 100 nanometers. In some embodiments, a thickness of the porous semiconductor material 812, e.g., a distance between the first side 814-1 and the second side 814-2, may be between about 20 nanometers and about 100 nanometers. In some embodiments, density of the pores 816 may be on the order of 10⁵ pores per cubic centimeter, e.g., at least 10¹⁵ pores per cubic centimeter or at least 10¹⁸ pores per cubic centimeter. In some embodiments, an area-to-volume ratio of the porous semiconductor material 812, which is a ratio between a surface area of the combined surface of all of the pores 816 in the porous semiconductor material 812 to the combined volume of all of the pores 816, may be relatively high. Any of the pores 816 may be irregularly shaped channels, i.e., the pores 816 are different from, e.g., via openings, etched in a material. In some embodiments, at least some of the pores 816 may have portions extending in a direction substantially parallel to the first side 814-1 or the second side 814-2, e.g., as shown in FIG. 9A with areas of the pores 816 within dotted contours 818.

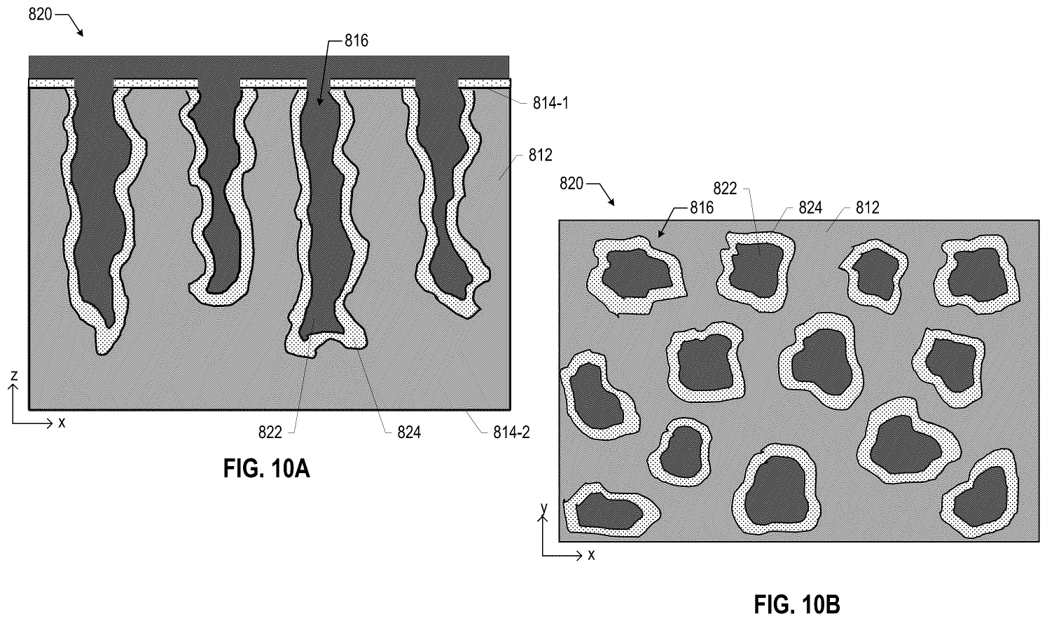

FIGS. 10A-10B illustrate examples of a cross-sectional side view and a top-down view of an IC structure 820 after a second stage of fabrication of a capacitor with a porous material being used as a capacitor electrode, according to some embodiments of the present disclosure. The IC structure 820 is the same as the IC structure 810, except that it further includes an insulator material 824 deposited to line surfaces of the pores 816, and further includes a conductive material 822 at least partially filling the pores 816 lined with the insulator material 824. The insulator material 824 may include any suitable insulator material, e.g., any of the insulator materials described with reference to the gate insulator 229 of the transistors 222. In some embodiments, the insulator material 824 may include a charge-trapping material, a FE material, an AFE material, a pyroelectric material, a charge injection material, or a workfunction (WF) modulated material.

The FE or AFE materials that may be included in the insulator material 824 may take form of any of the FE or AFE materials (or, more generally, hysteretic materials) described above with reference to materials that may be used as the gate insulators 229 of the transistors 222. For example, in various embodiments, FE or AFE materials that may be included in the insulator material 824 may include insulator materials having at least 5% being in an orthorhombic phase and/or in a tetragonal phase, and/or may include insulator materials that include hafnium, oxygen, and one or more of zirconium, silicon, germanium, aluminum, and yttrium (e.g., as dopants). Similarly, the charge-trapping material that may be included in the insulator material 824 may take form of any of the hysteretic arrangements described above with reference to materials that may be used as the gate insulators 229 of the transistors 222. For example, in some embodiments, a charge-trapping material that may be included in the insulator material 824 may include an insulator material comprising silicon and nitrogen. A pyroelectric material that may be included in the insulator material 824 may take form of any insulator materials that can exhibit spontaneous electric polarization that can be altered by changes in temperature. Examples of pyroelectric materials that may be included in the insulator material 824 include lead zirconate titanate (PZT), lithium tantalate, barium titanate, and polyvinylidene fluoride (which is a polymer-based pyroelectric material). A charge injection material that may be included in the insulator material 824 may take form of any materials that can provide electrical insulation between capacitor electrodes of the IC structure 820 while still allowing for efficient charge injection. These materials typically have high dielectric constants and may be chosen to have suitable energy levels and interface properties to facilitate charge injection without causing leakage currents. Examples of charge injection materials that may be included in the insulator material 824 include silicon dioxide, silicon nitride, aluminum oxide, or hafnium oxide. A WF modulated material that may be included in the insulator material 824 may take form of any materials that can control the energy barriers at the interfaces between different layers, thereby influencing charge injection, transport, and device performance. WF modulated materials of the insulator material 824 may have a varying workfunction profile across their thickness, allowing for precise tuning of the energy levels at the interfaces between the insulator material 824 and adjacent layers. Examples of WF modulated materials that may be included in the insulator material 824 include metal-insulator-semiconductor (MIS) structures incorporating an insulating layer between a metal layer and a semiconductor layer, transition metal oxides (e.g., molybdenum oxide (MoOx), tungsten oxide (WOx)), transition metal dichalcogenides (TMDs) (e.g., molybdenum disulfide (MoS2), tungsten diselenide (WSe2)), organic/inorganic hybrid materials, self-assembled monolayers (SAMs), or nanomaterials (e.g., quantum dots, nanoparticles). In some embodiments, the insulator material 824 in at least some of the pores 816 may include insulator materials that are not charge-trapping material, FE materials, AFE materials, pyroelectric materials, charge injection materials, or WF modulated materials. For example, in some embodiments, the insulator material 824 in at least some of the pores 816 may include a high-k dielectric material.

The insulator material 824 may be deposited using any suitable deposition technique, e.g., any suitable conformal deposition technique such as ALD or CVD, to provide a thin layer of the insulator material 824 on the surfaces of the pores 816. In some embodiments, a thickness of the insulator material 824 on the surfaces of the pores 816 may be between about 1 nanometer and about 10 nanometers, e.g., between about 1 nanometer and about 7 nanometers, or between about 2 nanometers and about 5 nanometers. The conductive material 822 may be deposited subsequently into the pores 816 lined with the insulator material 824 using any suitable deposition technique, such as PVD, CVD, ALD, electroplating, spin-coating, etc. The conductive material 822 may include any suitable conductive materials, e.g., any of the conductive metals or metal alloys described herein, any suitable metal nitrides (e.g., transition metal nitrides), any suitable metal carbides (e.g., transition metal carbides), or any other conductive materials. In some embodiments, the conductive material 822 in various pores 816 may be materially continuous with one another, e.g., by virtue of having a layer of the conductive material 822 over the first side 814-1 of the porous semiconductor material 812, as shown in FIG. 10A. The conductive material 822 is electrically isolated from the electrically conductive porous semiconductor material 812 by the layer of the insulator material 824 on the sidewalls of the pores 816 and on top of the first side 814-1. Thus, as shown in FIG. 9A, within each of the pores 816, the insulator material 824 may be between a surface of the pore and the conductive material 822, and, similarly, at the first side 814-1, the insulator material 824 may be between the first side 814-1 and the layer of the conductive material 822 over the first side 814-1. The IC structure 820 may, thus, provide a capacitor with a porous material, where the porous semiconductor material 812 is a first capacitor electrode, the conductive material 822 is a second capacitor electrode, and the insulator material 824 is a capacitor insulator.

FIGS. 10A-10B illustrate a capacitor similar to the planar capacitor 300 shown in FIG. 3A, but where the second capacitor electrode 302-2 of the capacitor 300 of FIG. 3A is the conductive material 822 shown in FIGS. 10A-10B, and where the first capacitor electrode 302-1 of the capacitor 300 of FIG. 3A is the porous semiconductor material 812 shown in FIGS. 10A-10B. In other embodiments, the porous semiconductor material 812 may be arranged in different architectures, to provide capacitors of other architectures. FIGS. 11-13 illustrate some embodiments of capacitors of other architectures that are based on the porous semiconductor material 812 with pores 816 lined with the insulator material 824 and then at least partially filled with the conductive material 822 as described with reference to FIGS. 9-10.

FIGS. 11A-11B illustrate examples of a cross-sectional side view and a top-down view of an IC structure 830 with a trench capacitor with a porous material being used as a capacitor electrode, according to some embodiments of the present disclosure. FIGS. 11A-11B illustrate a capacitor similar to the trench capacitor 300 shown in FIG. 3B, but where the second capacitor electrode 302-2 of the capacitor 300 of FIG. 3B is the conductive material 822 shown in FIGS. 11A-11B, and where the first capacitor electrode 302-1 of the capacitor 300 of FIG. 3B is the porous semiconductor material 812 shown in FIGS. 11A-11B. What is different from the planar capacitor arrangement of FIGS. 10A-10B is that, in FIGS. 11A-11B, the porous semiconductor material 812 includes a trench opening 832 and the pores 816 extend from the first side 814-1 of the porous semiconductor material 812 within the trench opening 832 and towards the second side 814-2 that is the side of the porous semiconductor material 812 opposite the inner surface of the trench opening 832. As shown in FIG. 1IA, the pores 816 may be provided at the sidewalls and the bottom of the trench opening 832 in some embodiments. In other embodiments, of the IC structure 830, the pores 816 may be provided at the sidewalls but not at the bottom of the trench opening 832, or the pores 816 may be provided at the bottom but not at the sidewalls of the trench opening 832. As also shown in FIG. 11A, if the capacitor with a porous semiconductor material is a trench capacitor, in a cross-section perpendicular to the device layer 220 of an IC structure (e.g., in the cross-section of FIG. 1IA), the porous semiconductor material 812 and the insulator material 824 may be U-shaped, except for the pores 816.

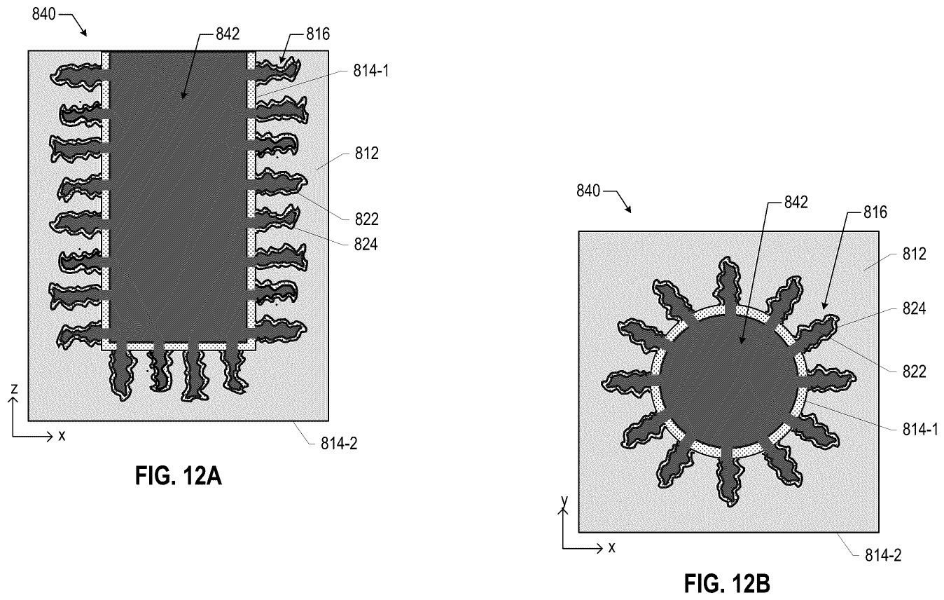

FIGS. 12A-12B illustrate examples of a cross-sectional side view and a top-down view of an IC structure 840 with a via capacitor with a porous material being used as a capacitor electrode, according to some embodiments of the present disclosure. FIGS. 12A-12B illustrate a capacitor similar to the trench capacitor shown in FIGS. 11A-11B, but where, instead of the trench opening 832, a via opening 842 is provided, which is substantially circular in it's top-down view. As shown in FIGS. 12A-12B, the porous semiconductor material 812 includes a via opening 842 and the pores 816 extend from the first side 814-1 of the porous semiconductor material 812 within the via opening 842 and towards the second side 814-2 that is the side of the porous semiconductor material 812 opposite the inner surface of the via opening 842. As shown in FIG. 12A, if the capacitor with a porous semiconductor material is a via capacitor, in a cross-section perpendicular to the device layer 220 of an IC structure (e.g., in the cross-section of FIG. 12A), the porous semiconductor material 812 and the insulator material 824 may be U-shaped, except for the pores 816.

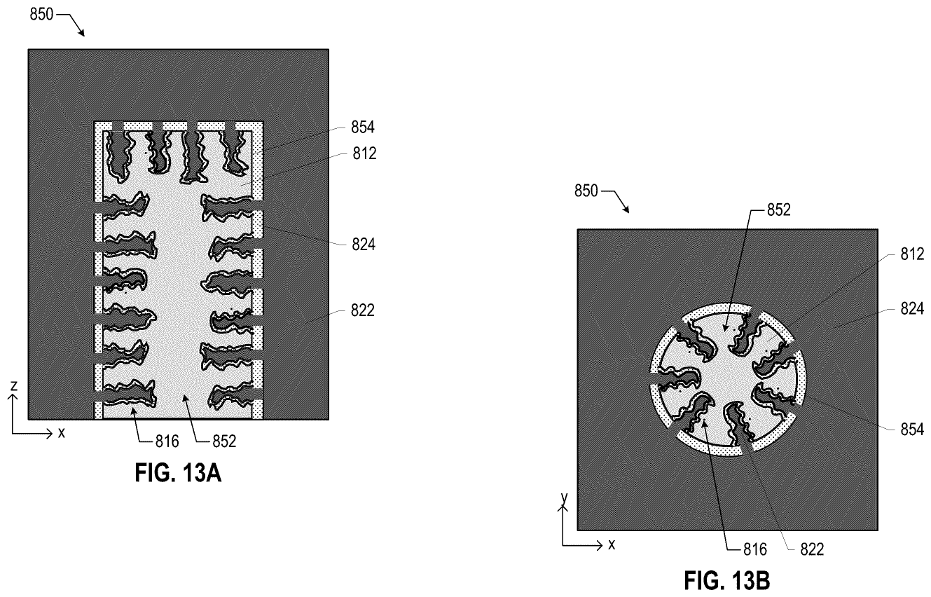

FIGS. 13A-13B illustrate examples of a cross-sectional side view and a top-down view of an IC structure 850 with a pillar capacitor with a porous material being used as a capacitor electrode, according to some embodiments of the present disclosure. FIGS. 13A-13B illustrate a capacitor similar to the pillar capacitor 300 shown in FIG. 3C, but where the second capacitor electrode 302-2 of the capacitor 300 of FIG. 3C is the conductive material 822 shown in FIGS. 13A-13B, and where the first capacitor electrode 302-1 of the capacitor 300 of FIG. 3C is the porous semiconductor material 812 shown in FIGS. 13A-13B. What is different from the planar capacitor arrangement of FIGS. 10A-10B is that, in FIGS. 13A-13B, the porous semiconductor material 812 is shaped as a pillar 852 and the pores 816 extend from the outer surface 854 of the pillar 852 into the pillar 852. As shown in FIG. 13A, if the capacitor with a porous semiconductor material is a pillar capacitor, in a cross-section perpendicular to the device layer 220 of an IC structure (e.g., in the cross-section of FIG. 13A), the conductive material 822 and the insulator material 824 may be U-shaped, except for when the conductive material 822 and the insulator material 824 are in the pores 816.

Various arrangements of the IC structures as illustrated in FIGS. 1-13 do not represent an exhaustive set of IC structures that may include capacitors with porous materials as described herein, but merely provide examples of such structures/devices/assemblies. For example, in further embodiments, a capacitor as shown in FIG. 3D may include a porous semiconductor material 812 instead of the first capacitor electrode 302-1. Any of the capacitors with porous materials as described herein may be implemented as one or more capacitors of the capacitor banks 242, 272, or 296 of the IC structures 200. The number and positions of various elements shown in FIGS. 1-13 is purely illustrative and, in various other embodiments, other numbers of these elements, provided in other locations relative to one another may be used in accordance with the general architecture considerations described herein.

The IC structures with capacitors with porous materials disclosed herein (e.g., any of the IC structures described with reference to FIGS. 1-13) may be included in any suitable electronic device. FIGS. 14-16 illustrate various examples of apparatuses that may include one or more IC structures with capacitors with porous materials disclosed herein.

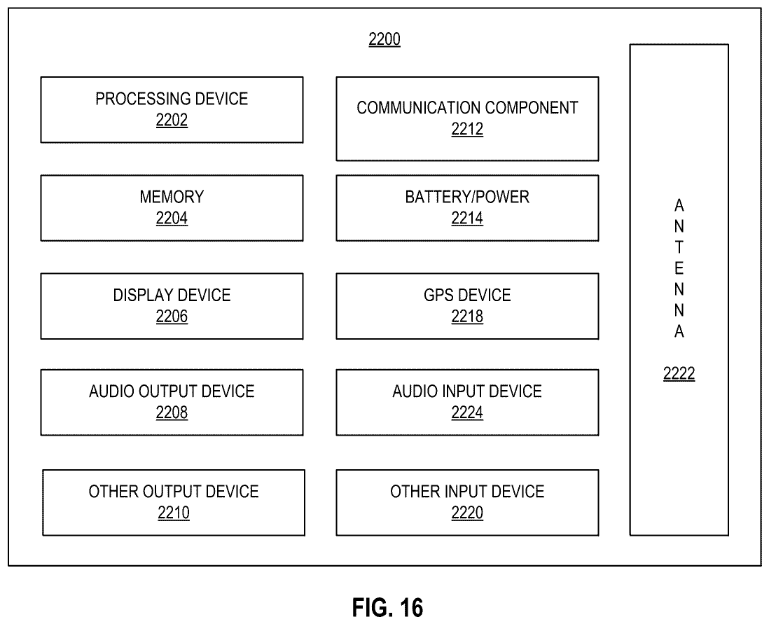

FIG. 14 illustrates top views of a wafer and dies that include one or more IC structures with capacitors with porous materials in accordance with any of the embodiments disclosed herein. The wafer 2000 may be composed of semiconductor material and may include one or more dies 2002 having IC structures formed on a surface of the wafer 2000. Each of the dies 2002 may be a repeating unit of a semiconductor product that includes any suitable IC structure (e.g., any of the IC structures described with reference to FIGS. 1-13). After the fabrication of the semiconductor product is complete (e.g., after manufacture of one or more IC structures with one or more capacitors with porous materials as described herein), the wafer 2000 may undergo a singulation process in which each of the dies 2002 is separated from one another to provide discrete “chips” of the semiconductor product. In particular, devices that include one or more IC structures with one or more capacitors with porous materials as disclosed herein may take the form of the wafer 2000 (e.g., not singulated) or the form of the die 2002 (e.g., singulated). The die 2002 may include one or more transistors (e.g., one or more of the transistors 222 of FIG. 2) and/or supporting circuitry to route electrical signals to the transistors, as well as any other IC components (e.g., one or more capacitors with porous materials as discussed herein). In some embodiments, the wafer 2000 or the die 2002 may include a memory device (e.g., a static random-access memory (SRAM) device), a logic device (e.g., an AND, OR, NAND, or NOR gate), or any other suitable circuit element. Multiple ones of these devices may be combined on a single die 2002. For example, a memory array formed by multiple memory devices may be formed on a same die 2002 as a processing device (e.g., the processing device 2202 of FIG. 16) or other logic that is configured to store information in the memory devices or execute instructions stored in the memory array.

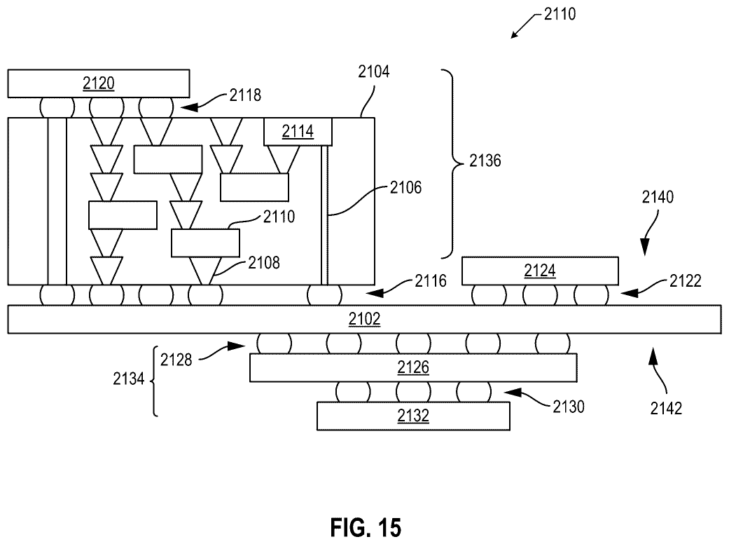

FIG. 15 illustrates a cross-sectional side view of an IC device assembly 2100 that may include components having or being associated with (e.g. being electrically connected by means of) one or more IC structures with one or more capacitors with porous materials in accordance with any of the embodiments disclosed herein. The IC device assembly 2100 includes a number of components disposed on a circuit board 2102 (which may be, e.g., a motherboard). The IC device assembly 2100 includes components disposed on a first face 2140 of the circuit board 2102 and an opposing second face 2142 of the circuit board 2102; generally, components may be disposed on one or both faces 2140 and 2142. In particular, any suitable ones of the components of the IC device assembly 2100 may include any of the IC structures with one or more capacitors with porous materials, disclosed herein.

In some embodiments, the circuit board 2102 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2102. In other embodiments, the circuit board 2102 may be a non-PCB substrate.

The IC device assembly 2100 illustrated in FIG. 15 includes a package-on-interposer structure 2136 coupled to the first face 2140 of the circuit board 2102 by coupling components 2116. The coupling components 2116 may electrically and mechanically couple the package-on-interposer structure 2136 to the circuit board 2102, and may include solder balls (as shown in FIG. 15), male and female portions of a socket, an adhesive, an underfill material, and/or any other suitable electrical and/or mechanical coupling structure.

The package-on-interposer structure 2136 may include an IC package 2120 coupled to an interposer 2104 by coupling components 2118. The coupling components 2118 may take any suitable form for the application, such as the forms discussed above with reference to the coupling components 2116. Although a single IC package 2120 is shown in FIG. 15, multiple IC packages may be coupled to the interposer 2104; indeed, additional interposers may be coupled to the interposer 2104. The interposer 2104 may provide an intervening substrate used to bridge the circuit board 2102 and the IC package 2120. The IC package 2120 may be or include, for example, a die (the die 2002 of FIG. 14), an IC device (e.g., any of the IC structures 200 of FIGS. 2A-2J), or any other suitable component. In some embodiments, the IC package 2120 may include one or more IC structures with one or more capacitors with porous materials, as described herein. Generally, the interposer 2104 may spread a connection to a wider pitch or reroute a connection to a different connection. For example, the interposer 2104 may couple the IC package 2120 (e.g., a die) to a ball grid array (BGA) of the coupling components 2116 for coupling to the circuit board 2102. In the embodiment illustrated in FIG. 15, the IC package 2120 and the circuit board 2102 are attached to opposing sides of the interposer 2104; in other embodiments, the IC package 2120 and the circuit board 2102 may be attached to a same side of the interposer 2104. In some embodiments, three or more components may be interconnected by way of the interposer 2104.

The interposer 2104 may be formed of an epoxy resin, a fiberglass-reinforced epoxy resin, a ceramic material, or a polymer material such as polyimide. In some implementations, the interposer 2104 may be formed of alternate rigid or flexible materials that may include the same materials described above for use in a semiconductor substrate, such as silicon, germanium, and other group Ill-V and group IV materials. The interposer 2104 may include metal interconnects 2108 and vias 2110, including but not limited to TSVs 2106. The interposer 2104 may further include embedded devices 2114, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 2104. The interposer 2104 may further include one or more capacitors with porous materials as described herein. The package-on-interposer structure 2136 may take the form of any of the package-on-interposer structures known in the art.

The IC device assembly 2100 may include an IC package 2124 coupled to the first face 2140 of the circuit board 2102 by coupling components 2122. The coupling components 2122 may take the form of any of the embodiments discussed above with reference to the coupling components 2116, and the IC package 2124 may take the form of any of the embodiments discussed above with reference to the IC package 2120.

The IC device assembly 2100 illustrated in FIG. 15 includes a package-on-package structure 2134 coupled to the second face 2142 of the circuit board 2102 by coupling components 2128. The package-on-package structure 2134 may include an IC package 2126 and an IC package 2132 coupled together by coupling components 2130 such that the IC package 2126 is disposed between the circuit board 2102 and the IC package 2132. The coupling components 2128 and 2130 may take the form of any of the embodiments of the coupling components 2116 discussed above, and the IC packages 2126 and 2132 may take the form of any of the embodiments of the IC package 2120 discussed above. The package-on-package structure 2134 may be configured in accordance with any of the package-on-package structures known in the art.

FIG. 16 illustrates a block diagram of an example computing device 2200 that may include one or more components including one or more IC structures with one or more capacitors with porous materials in accordance with any of the embodiments disclosed herein. For example, any suitable ones of the components of the computing device 2200 may include a die (e.g., the die 2002 of FIG. 14) having one or more capacitors with porous materials as described herein. Any one or more of the components of the computing device 2200 may include, or be included in, an IC structure with one or more capacitors with porous materials as described herein, e.g., any of the IC structures 200 of FIGS. 2A-2J. Any one or more of the components of the computing device 2200 may include, or be included in, an IC device assembly 2100 of FIG. 15.

A number of components are illustrated in FIG. 16 as included in the computing device 2200, but any one or more of these components may be omitted or duplicated, as suitable for the application. In some embodiments, some or all of the components included in the computing device 2200 may be attached to one or more motherboards. In some embodiments, some or all of these components are fabricated onto a single system-on-a-chip (SoC) die.

Additionally, in various embodiments, the computing device 2200 may not include one or more of the components illustrated in FIG. 16, but the computing device 2200 may include interface circuitry for coupling to the one or more components. For example, the computing device 2200 may not include a display device 2206, but may include display device interface circuitry (e.g., a connector and driver circuitry) to which a display device 2206 may be coupled. In another set of examples, the computing device 2200 may not include an audio input device 2224 or an audio output device 2208, but may include audio input or output device interface circuitry (e.g., connectors and supporting circuitry) to which an audio input device 2224 or audio output device 2208 may be coupled.

The computing device 2200 may include a processing device 2202 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2202 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 2200 may include a memory 2204, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, the memory 2204 may include memory that shares a die with the processing device 2202. This memory may be used as cache memory and may include embedded dynamic random-access memory (eDRAM) or spin transfer torque magnetic random-access memory (STT-MRAM).

In some embodiments, the computing device 2200 may include a communication chip 2212 (e.g., one or more communication chips). For example, the communication chip 2212 may be configured for managing wireless communications for the transfer of data to and from the computing device 2200. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2212 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2212 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2212 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2212 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 20G, 21G, and beyond. The communication chip 2212 may operate in accordance with other wireless protocols in other embodiments. The computing device 2200 may include an antenna 2222 to facilitate wireless communications and/or to receive other wireless communications (such as AM or FM radio transmissions).

In some embodiments, the communication chip 2212 may manage wired communications, such as electrical, optical, or any other suitable communication protocols (e.g., the Ethernet). As noted above, the communication chip 2212 may include multiple communication chips. For instance, a first communication chip 2212 may be dedicated to shorter-range wireless communications such as Wi-Fi or Bluetooth, and a second communication chip 2212 may be dedicated to longer-range wireless communications such as global positioning system (GPS), EDGE, GPRS, CDMA, WiMAX, LTE, EV-DO, or others. In some embodiments, a first communication chip 2212 may be dedicated to wireless communications, and a second communication chip 2212 may be dedicated to wired communications.

The computing device 2200 may include battery/power circuitry 2214. The battery/power circuitry 2214 may include one or more energy storage devices (e.g., batteries or capacitors) and/or circuitry for coupling components of the computing device 2200 to an energy source separate from the computing device 2200 (e.g., AC line power).

The computing device 2200 may include a display device 2206 (or corresponding interface circuitry, as discussed above). The display device 2206 may include any visual indicators, such as a heads-up display, a computer monitor, a projector, a touchscreen display, a liquid crystal display (LCD), a light-emitting diode display, or a flat panel display, for example.

The computing device 2200 may include an audio output device 2208 (or corresponding interface circuitry, as discussed above). The audio output device 2208 may include any device that generates an audible indicator, such as speakers, headsets, or earbuds, for example.

The computing device 2200 may include an audio input device 2224 (or corresponding interface circuitry, as discussed above). The audio input device 2224 may include any device that generates a signal representative of a sound, such as microphones, microphone arrays, or digital instruments (e.g., instruments having a musical instrument digital interface (MIDI) output).

The computing device 2200 may include a GPS device 2218 (or corresponding interface circuitry, as discussed above). The GPS device 2218 may be in communication with a satellite-based system and may receive a location of the computing device 2200, as known in the art.

The computing device 2200 may include an other output device 2210 (or corresponding interface circuitry, as discussed above). Examples of the other output device 2210 may include an audio codec, a video codec, a printer, a wired or wireless transmitter for providing information to other devices, or an additional storage device.

The computing device 2200 may include an other input device 2220 (or corresponding interface circuitry, as discussed above). Examples of the other input device 2220 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2200 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2200 may be any other electronic device that processes data.

The following paragraphs provide various examples of the embodiments disclosed herein.

Example 1 provides an IC structure that includes a capacitor having a first electrode, a second electrode, and an insulator between the first electrode and the second electrode, in which the first electrode includes a semiconductor material with dopants, and in which the semiconductor material is a porous semiconductor material.

Example 2 provides the IC structure according to example 1, in which the porous semiconductor material includes pores having sizes between 10 nanometers and 100 nanometers.

Example 3 provides the IC structure according to examples 1 or 2, in which the porous semiconductor material does not include any pores having sizes greater than 100 nanometers.

Example 4 provides the IC structure according to any one of examples 1-3, in which, for an individual pore of a plurality of pores of the porous semiconductor material: the insulator and a conductive material of the second electrode are in the individual pore, and the insulator is between a surface of the pore and the conductive material.

Example 5 provides the IC structure according to example 4, in which the conductive material in multiple pores of the plurality of pores is a materially continuous conductive material.

Example 6 provides the IC structure according to any one of examples 1-5, in which a dopant concentration of the dopants in the semiconductor material is at least about 10¹⁸ dopants per cubic centimeter.

Example 7 provides the IC structure according to any one of examples 1-6, further including a substrate having a first side and a second side opposite the first side; a layer including transistors over the first side of the substrate; and an interconnect layer including a plurality of interconnects, in which the layer including transistors is between the first side of the substrate and the interconnect layer.

Example 8 provides the IC structure according to example 7, in which the capacitor is in the interconnect layer (i.e., the capacitor is closer to the first side of the substrate than to the second side of the substrate).

Example 9 provides the IC structure according to example 7, in which the capacitor is closer to the second side of the substrate than to the first side of the substrate.

Example 10 provides the IC structure according to example 7, in which the interconnect layer is a first interconnect layer, and the IC structure further includes a second interconnect layer, in which: the substrate is between the first interconnect layer and the second interconnect layer, and the capacitor is in the second interconnect layer.

Example 11 provides the IC structure according to any one of examples 1-6, further including an IC die; and a further component coupled to the IC die, in which the IC die includes the capacitor, and in which the further component is one of a package substrate, an interposer, or a further IC die.

Example 12 provides an IC structure that includes a structure of an insulator material, the structure having a first side and a second side opposite the first side, in which the insulator material is a porous insulator material having first pores extending into the structure from the first side towards the second side and further having second pores extending into the structure from the second side towards the first side; a first conductive material at least partially filling the first pores; and a second conductive material at least partially filling the second pores.

Example 13 provides the IC structure according to example 12, in which the first pores and the second pores have sizes between 5 nanometers and 20 nanometers.

Example 14 provides the IC structure according to examples 12 or 13, in which the first pores and the second pores do not include any pores having sizes greater than about 20 nanometers.

Example 15 provides the IC structure according to any one of examples 12-14, in which the insulator material includes a semiconductor material and oxygen (e.g., a semiconductor oxide, e.g., silicon oxide).

Example 16 provides the IC structure according to any one of examples 12-15, in which the first pores have portions extending in a direction substantially parallel to the first side.

Example 17 provides the IC structure according to any one of examples 12-16, in which the first pores are irregularly shaped channels.

Example 18 provides the IC structure according to any one of examples 12-17, in which the first conductive material and the second conductive material are separated by the insulator material.

Example 19 provides a method of fabricating an IC structure, the method including providing a structure of a semiconductor material, the structure having a first side and a second side opposite the first side, in which the semiconductor material is a porous semiconductor material having pores extending into the structure from the first side towards the second side; depositing an insulator material on sidewalls of the pores; and depositing a conductive material into the pores with the insulator material on the sidewalls of the pores.

Example 20 provides the method according to example 19, in which depositing the insulator material includes depositing the insulator material using a conformal deposition technique.

Example 21 provides an IC package, including an IC die, including an IC structure; and a further component, coupled to the IC die, in which the IC structure is an IC structure according to any one of the preceding examples.

Example 22 provides the IC package according to example 21, in which the further component is one of a package substrate, an interposer, or a further IC die.

Example 23 provides an electronic device, including a carrier substrate; and one or more of the IC structures according to any one of the preceding examples and/or the IC package according to any one of the preceding claims, coupled to the carrier substrate.

Example 24 provides the electronic device according to example 23, in which the carrier substrate is a motherboard.

Example 25 provides the electronic device according to example 23, in which the carrier substrate is a PCB.

Example 26 provides the electronic device according to any one of examples 23-25, in which the electronic device is a wearable electronic device (e.g., a smart watch) or handheld electronic device (e.g., a mobile phone).

Example 27 provides the electronic device according to any one of examples 23-26, in which the electronic device further includes one or more communication chips and an antenna.

Example 28 provides the electronic device according to any one of examples 23-27, in which the electronic device is memory device.

Example 29 provides the electronic device according to any one of examples 23-27, in which the electronic device is one of an RF transceiver, a switch, a power amplifier, a low-noise amplifier, a filter, a filter bank, a duplexer, an upconverter, or a downconverter of an RF communications device, e.g., of an RF transceiver.

Example 30 provides the electronic device according to any one of examples 23-27, in which the electronic device is a computing device.

Example 31 provides the electronic device according to any one of examples 23-30, in which the electronic device is included in a base station of a wireless communication system.

Example 32 provides the electronic device according to any one of examples 23-30, in which the electronic device is included in a user equipment device (i.e., a mobile device) of a wireless communication system.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) structure, comprising:
a capacitor, comprising:
a first electrode,
a second electrode, and
an insulator between the first electrode and the second electrode,
wherein the first electrode includes a semiconductor material with dopants, and wherein the semiconductor material is a porous semiconductor material.

2. The IC structure according to claim 1, wherein the porous semiconductor material includes pores having sizes between 10 nanometers and 100 nanometers.

3. The IC structure according to claim 1, wherein the porous semiconductor material does not include any pores having sizes greater than 100 nanometers.

4. The IC structure according to claim 1, wherein, for an individual pore of a plurality of pores of the porous semiconductor material:
the insulator and a conductive material of the second electrode are in the individual pore, and
the insulator is between a surface of the pore and the conductive material.

5. The IC structure according to claim 4, wherein the conductive material in multiple pores of the plurality of pores is a materially continuous conductive material.

6. The IC structure according to claim 1, wherein a dopant concentration of the dopants in the semiconductor material is at least about 10¹⁸ dopants per cubic centimeter.

7. The IC structure according to claim 1, further comprising:
a substrate having a first side and a second side opposite the first side;
a layer comprising transistors over the first side of the substrate; and
an interconnect layer comprising a plurality of interconnects,
wherein the layer comprising transistors is between the first side of the substrate and the interconnect layer.

8. The IC structure according to claim 7, wherein the capacitor is in the interconnect layer.

9. The IC structure according to claim 7, wherein the capacitor is closer to the second side of the substrate than to the first side of the substrate.

10. The IC structure according to claim 7, wherein the interconnect layer is a first interconnect layer, and the IC structure further includes a second interconnect layer, wherein:
the substrate is between the first interconnect layer and the second interconnect layer, and
the capacitor is in the second interconnect layer.

11. The IC structure according to claim 1, further comprising:
an IC die; and
a further component coupled to the IC die,
wherein the IC die includes the capacitor, and wherein the further component is one of a package substrate, an interposer, or a further IC die.

12. An integrated circuit (IC) structure, comprising:
a structure of an insulator material, the structure having a first side and a second side opposite the first side, wherein the insulator material is a porous insulator material having first pores extending into the structure from the first side towards the second side and further having second pores extending into the structure from the second side towards the first side;
a first conductive material at least partially filling the first pores; and
a second conductive material at least partially filling the second pores.

13. The IC structure according to claim 12, wherein the first pores and the second pores have sizes between 5 nanometers and 20 nanometers.

14. The IC structure according to claim 12, wherein the first pores and the second pores do not include any pores having sizes greater than about 20 nanometers.

15. The IC structure according to claim 12, wherein the insulator material includes a semiconductor material and oxygen.

16. The IC structure according to claim 12, wherein the first pores have portions extending in a direction substantially parallel to the first side.

17. The IC structure according to claim 12, wherein the first pores are irregularly shaped channels.

18. The IC structure according to claim 12, wherein the first conductive material and the second conductive material are separated by the insulator material.

19. A method of fabricating an integrated circuit (IC) structure, the method comprising:
providing a structure of a semiconductor material, the structure having a first side and a second side opposite the first side, wherein the semiconductor material is a porous semiconductor material having pores extending into the structure from the first side towards the second side;
depositing an insulator material on sidewalls of the pores; and
depositing a conductive material into the pores with the insulator material on the sidewalls of the pores.

20. The method according to claim 19, wherein depositing the insulator material includes depositing the insulator material using a conformal deposition technique.
